(19) United States
(12) Patent Application Publication
(10) Pub. No.: US 2025/0359192 A1
(43) Pub. Date: Nov. 20, 2025

(54) SYSTEM AND METHOD FOR HIGH STRESS TRANSFER TO CHANNEL

(71) Applicant: Samsung Electronics Co., Ltd., Gyeonggi-do (KR)

(72) Inventors: Aravindh KUMAR, Mountain View, CA (US); Mehdi SAREMI, Danville, CA (US); Ming HE, San Jose, CA (US); Muhammed AHOSAN UL KARIM, San Jose, CA (US); Rebecca PARK, Mountain View, CA (US); Harsono SIMKA, Saratoga, CA (US)

(21) Appl. No.: 19/050,806

(22) Filed: Feb. 11, 2025

Related U.S. Application Data
(60) Provisional application No. 63/647,901, filed on May 15, 2024.

(51) Int. Cl. H10D 30/69; H10D 62/00; H10D 62/13

(52) U.S. Cl. CPC H10D 30/797; H10D 62/021; H10D 62/151

(57) ABSTRACT

A method, apparatus, and system are provided. The method includes the steps of depositing a dummy stressor into a source and drain (S/D) region between a first sidewall and a second sidewall of a transistor before an epitaxial (EPI) layer is deposited into the S/D region; removing a polysilicon fin between the second sidewall and a third sidewall of the transistor to expose an initial stack; removing the dummy stressor from the S/D region; and depositing the EPI layer into the S/D region.

### PRIORITY

This application is based on and claims priority under 35 U.S.C. § 119(e) to U.S. Provisional Patent Application Ser. No. 63/647,901, filed on May 15, 2024, the entire contents of which are incorporated herein by reference.

### TECHNICAL FIELD

The disclosure generally relates to semiconductor design. More particularly, the subject matter disclosed herein relates to improvements to applying stress in transistors.

### SUMMARY

The semiconductor industry is transitioning from fin field-effect transistor (FinFET) towards more advanced transistor technologies such as nanosheet multi-bridge channel field-effect transistor (MBCFET) transistors, forksheet transistors, and complementary field-effect transistor (CFET) or three-dimensional stacked field-effect transistor (3DS-FET) devices. These advanced transistor technologies are expected to drive scaling for the foreseeable future. One of the challenges in this transition is maintaining and improving performance of these transistors through stress engineering.

Stress engineering via epitaxial (EPI) growth of source and drain (S/D) regions is a method to boost the performance of planar transistors and FinFETs. This method involves growing a crystalline layer on the Silicon (Si) substrate to induce stress in the transistor channel, enhancing carrier mobility and, improving the transistor's performance. However, as transistors scale down and adopt more advanced structures, they lack continuous surfaces necessary for EPI, leading to defects such as stacking faults and dislocations. These defects can significantly reduce the efficiency of stress transfer to the transistor channel, thereby diminishing the performance improvements that can be achieved through standard stress engineering methods.

To address these types of problems with reduced stress transfer efficiency in advanced transistors with discontinuous surfaces, embodiments described herein provide systems and methods to engineer stress in the transistor channel. The systems and methods may include depositing and/or removing a stressor material in the S/D regions before the EPI module. By introducing the stressor material at this stage, the stress can be transferred more efficiently into the Si channel, enhancing the overall performance of the transistor.

An aspect of the disclosure leverages a low-temperature EPI solution, which allows the stressor material to be positioned closer to the Si channel, thereby maximizing stress transfer efficiency. This low-temperature process also mitigates the risk of damaging other components in the transistor stack, such as the high-k metal gate (HKMG) stack, which cannot withstand high thermal budgets typically associated with high-temperature EPI.

Accordingly, the present disclosure provides systems and methods of depositing and/or removing a dummy stressor material in the S/D regions before the EPI module, which significantly improves stress transfer efficiency to the transistor channel. The systems and methods may be particularly suited for advanced transistor structures with discontinuous EPI surfaces, ensuring that the performance of next-generation transistors are effectively enhanced through optimized stress engineering.

According to an aspect of the disclosure, a method of fabricating a transistor includes the steps of depositing a dummy stressor into an S/D region between a first sidewall and a second sidewall of the transistor before an EPI layer is deposited into the S/D region; removing a polysilicon fin between the second sidewall and a third sidewall of the transistor to expose an initial stack; removing the dummy stressor from the S/D region; and depositing the EPI layer into the S/D region.

According to another aspect of the disclosure, a transistor includes a dummy stressor deposited into an S/D region between a first sidewall and a second sidewall of the transistor; an initial stack exposed by removing a polysilicon fin between the second sidewall and a third sidewall of the transistor; and an EPI layer deposited into the S/D region, wherein the dummy stressor is removed from the S/D region before the EPI layer is deposited into the S/D region.

According to another aspect of the disclosure, a fabrication system includes a deposition controller configured to deposit a dummy stressor into an S/D region between a first sidewall and a second sidewall of a transistor before an EPI layer is deposited into the S/D region, and deposit the EPI layer into the S/D region; and a removal controller configured to remove a polysilicon fin between the second sidewall and a third sidewall of the transistor to expose an initial stack, and remove the dummy stressor from the S/D region.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIGS. 1-20 illustrate example systems in accordance with one or more implementations as described herein;

FIG. 21 illustrates three types of transistor structures used in integrated circuits (ICs) in accordance with one or more implementations as described herein;

FIG. 22 illustrates an ideal scenario for EPI growth used to enhance transistor performance in accordance with one or more implementations as described herein;

FIG. 23 illustrates a non-ideal scenario for EPI growth used to enhance transistor performance in accordance with one or more implementations as described herein;

FIGS. 24A-24B illustrate a process flow for fabricating a transistor using a gate first process in accordance with one or more implementations as described herein;

FIG. 25 is a flowchart illustrating a method of fabricating a transistor in accordance with one or more implementations as described herein; and

FIG. 26 illustrates an example system in accordance with one or more implementations as described herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments.

Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an IC, system on-a-chip (SoC), an assembly, and so forth.

A channel region of a p-channel metal-oxide semiconductor (PMOS) transistor may be configured with compressive stress (e.g., −1 GigaPascal (GPa), negative compression) to boost hole mobility, while a channel region of an n-channel metal-oxide semiconductor (NMOS) transistor may be configured with tensile stress (e.g., +1 GPa, positive compression) to boost electron mobility. A negative stress (e.g., −1.5 GPa) may be referred to as compressive stress, while a positive stress (e.g., +1.5 GPa) may be referred to as a tensile stress. Applying stress (e.g., to an Si channel region of a transistor) can provide a performance boost. The strain in a channel region can depend on the intrinsic stress of the layer, thickness of the layer, and device dimensions. Herein, “increasing stress” can be interpreted as increasing tensile stress or interpreted as increasing compressive stress in the channel region of NMOS transistors or in the channel region of PMOS transistors. Similarly, “decreasing stress” can be interpreted as decreasing tensile stress or interpreted as decreasing compressive stress in the channel region of NMOS transistors or in the channel region of PMOS transistors.

Higher stress generally results in improved drive current. Stress engineering via EPI growth of S/D regions has been one approach to boosting the performance in planar transistors and FinFETs. However, in some cases, an EPI stressor may not be an efficient stressor in advanced transistor structures having a discontinuous surface for S/D EPI growth. The presence of an inner spacer and/or bottom dielectric isolation (BDI) can result in a discontinuous surface for EPI growth. Discontinuous surfaces for EPI growth may result in defects, such as stacking faults and dislocations, which in turn may fail to provide a desired level of stress. For example, EPI film as a stressor may not provide reliable stress for some transistors, such as MBCFETs, Forksheet transistors, CFETs or 3DS-FET devices.

The systems and methods described herein provide a process to transfer stress into a transistor channel by depositing and/or removing a stressor material in the S/D region of the transistor before EPI growth in the region. Additionally, the systems and methods provide a process for depositing the stressor material before depositing a metal gate (e.g., before replacement metal gate (RMG)), which improves stress transfer efficiency. The stress in the channel may be significantly greater when the stressor is deposited before the RMG compared to being deposited after the RMG. Depositing the stressor material before the RMG allows the RMG to lock in the stress profile. Thus, with the RMG locking in the stress profile, the stressor material can then be removed without adversely affecting the stress profile.

With some approaches, an EPI has been used as a stressor in the S/D region of a transistor. In some cases, an Si germanium (SiGe) EPI film may be used as a stressor (e.g., for PMOS transistors). In some cases, an Si carbide (SiC) EPI film may be used as a stressor (e.g., for NMOS transistors). With some transistors, the EPI film may result in a discontinuous surface in the EPI film (e.g., discontinuous or disjointed EPI growth). A discontinuous surface in the EPI film may cause defects (i.e., stacking faults, dislocation, etc.).

Furthermore, the systems and methods described herein may use materials other than EPI films for stressor materials. The systems and methods may include depositing a material having a high intrinsic stress to transfer the stress into an Si channel region. The systems and methods may be applicable to transistor structures that do not allow a continuous surface for EPI growth in S/D regions.

Stress engineering, therefore, can play a crucial role in semiconductor device performance. The amount of stress applied depends on several factors, including the intrinsic stress of the stressor material, the thickness of the layers involved, and the dimensions of the device. Increasing or decreasing stress in the channel region can be tailored to achieve optimal performance for specific transistor types.

Accordingly, technologies disclosed in this application provide a system and method to enhance stress transfer efficiency in advanced semiconductor devices, particularly those with discontinuous surfaces such as nanosheet MBCFETs, forksheet transistors, and CFETs. Embodiments disclosed herein address the challenge of reduced stress transfer efficiency caused by defects like stacking faults and dislocations that arise from EPI growth techniques. By depositing and/or removing a stressor material in the S/D regions before the EPI growth, the process ensures a more efficient transfer of stress into the Si channel, thereby boosting the overall performance of the transistor.

As will be described herein, an aspect of this approach involves the use of low-temperature EPI, which allows the stressor material to be positioned closer to the Si channel without damaging other components in the transistor stack, such as the HKMG stack. This positioning maximizes stress transfer efficiency, ensuring that the desired mechanical strain is effectively applied to enhance carrier mobility within the channel. The process flow is further optimized by using a dummy stressor material, which can be any material with high intrinsic stress, and is subsequently removed after it has fulfilled its role in stress transfer.

“Dummy stressor” as used herein may refer to a temporary material deposited in an S/D region of a transistor to introduce stress into the Si channel. A purpose of the dummy stressor is to enhance carrier mobility by creating mechanical stress, which is beneficial for the transistor's performance. Some examples of “dummy stressor” materials are high-stress dielectrics or temporary metals that can be easily removed in subsequent processing steps.

“S/D region” as used herein may refer to a trench formed during the transistor fabrication process, which is located in line with the Si channel and positioned between the dummy gate structures. The S/D region may be initially created by etching through a nanosheet stack or fin, along with the gate spacer, to open up space for subsequent processing. This S/D region may later be filled with a dummy stressor material to introduce mechanical stress into the Si channel. After the RMG process, the dummy stressor can be removed, and an EPI layer can be grown in the S/D region. Following EPI growth, metal electrodes may be deposited on top of the EPI to form the source and drain contacts.

“Polysilicon fin” as used herein may refer to a temporary structure made of polysilicon that is used during the initial stages of transistor fabrication. The polysilicon fin serves as a placeholder and helps define the regions where the source, drain, and gate will be formed. It may be removed after certain layers and structures are formed. The removal of the polysilicon fin exposes the underlying layers for further processing.

“Initial stack” as used herein may refer to the layered structure formed on the Si substrate before detailed transistor features are defined. The initial stack includes multiple layers, such as SiGe and other materials that introduce stress into the Si channel. The initial stack serves as the foundation for subsequent etching and deposition processes that create the final transistor structure.

“Channel structure” as used herein may refer to the structural component of a transistor that forms the conductive channel through which current flows between the source and drain regions. The channel structure may be a horizontally oriented Si structure, such as a nanosheet, over which the gate is formed, allowing for improved control of the current flow through the channel. The channel structure may be situated between the S/D regions and increase the surface area for the gate contact to enhance the electrostatic control over the channel.

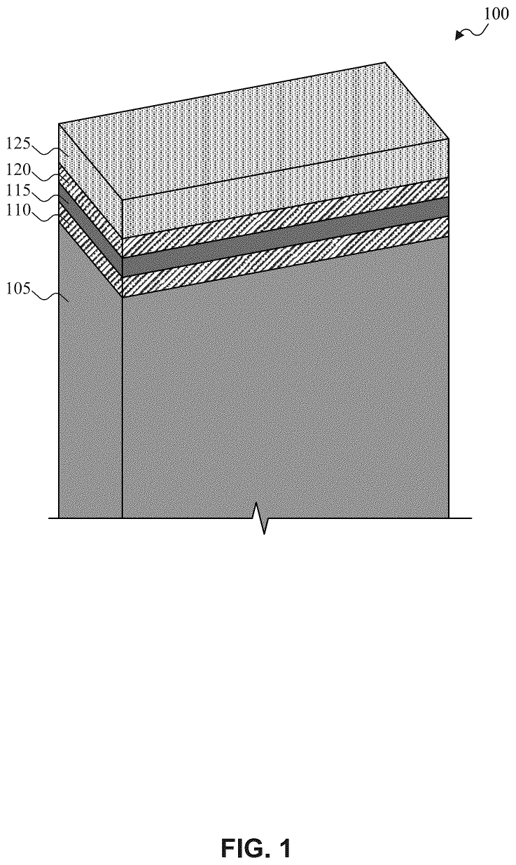

FIG. 1 illustrates an example stack 100 in accordance with one or more implementations as described herein.

Referring to FIG. 1, in some examples, stack 100 may depict layers of a semiconductor device (e.g., a semiconductor stack of a transistor). In the illustrated example, stack 100 may include a substrate 105, a semiconductor alloy 110, a semiconductor 115, a semiconductor alloy 120, and a dielectric 125 (e.g., Si nitride). In some examples, semiconductor alloy 110 may be deposited on substrate 105, semiconductor 115 may be deposited on semiconductor alloy 110, semiconductor alloy 120 may be deposited on semiconductor 115, and dielectric 125 may be deposited on semiconductor alloy 120. In some examples, a transistor may be configured with one semiconductor channel (e.g., semiconductor 115). In some cases, a transistor may be configured with two or more semiconductor channels (e.g., based on a vertical stack, a taller stack).

In some examples, substrate 105 may include an Si substrate. A contacted poly pitch (CPP), or transistor gate pitch, of stack 100 may be, for example, in the nanometer or micrometer scale. In some cases, semiconductor alloy 110 and/or semiconductor alloy 120 may include SiGe. In some cases, semiconductor 115 may include Si. Semiconductor 115 may form an Si channel region of stack 100. A lattice mismatch may occur between semiconductor alloy 110, semiconductor 115, and semiconductor alloy 120, which can result in compressive stress in semiconductor alloy 110 and/or semiconductor alloy 120 (e.g., compressive stress in SiGe layers). For example, semiconductor alloy 110 and/or semiconductor alloy 120 may have a compressive stress level. In stack 100, there may be relatively little to no stress in semiconductor 115 (e.g., in the Si channel region). The stress level in semiconductor 115 may vary based on channel dimension and other fabrication parameters.

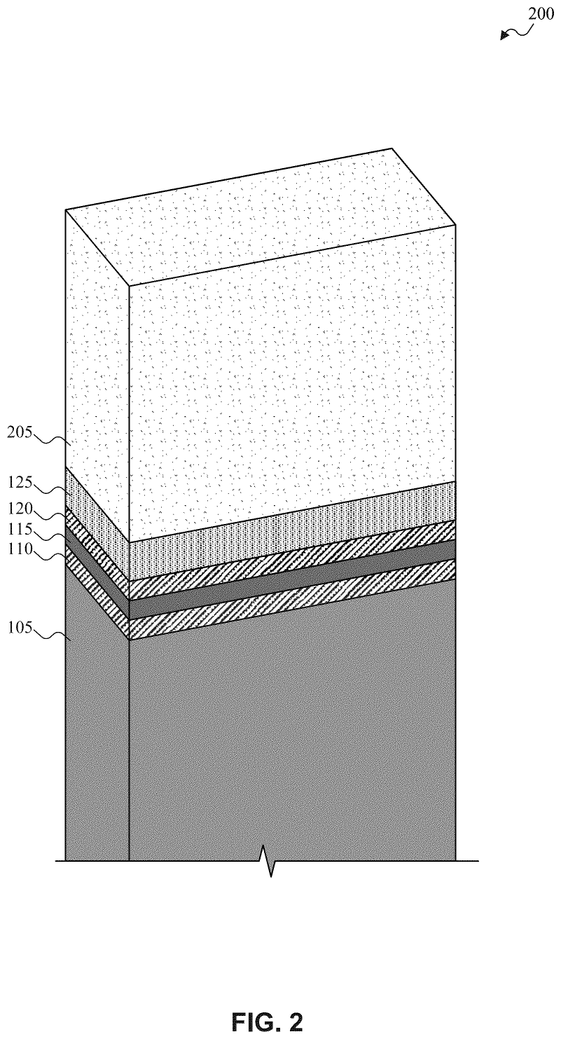

FIG. 2 illustrates an example stack 200 in accordance with one or more implementations as described herein.

Referring to FIG. 2, in some examples, stack 200 may depict layers of a semiconductor device (e.g., a semiconductor stack of a transistor). In the illustrated example, stack 200 may include substrate 105, semiconductor alloy 110, semiconductor 115, semiconductor alloy 120, dielectric 125, and mask 205. In some cases, mask 205 may include a photoresist mask. A photoresist mask can include a light-sensitive material that is used to create a pattern or mask that blocks light from a surface in semiconductor fabrication. As shown, mask 205 may be deposited on dielectric 125.

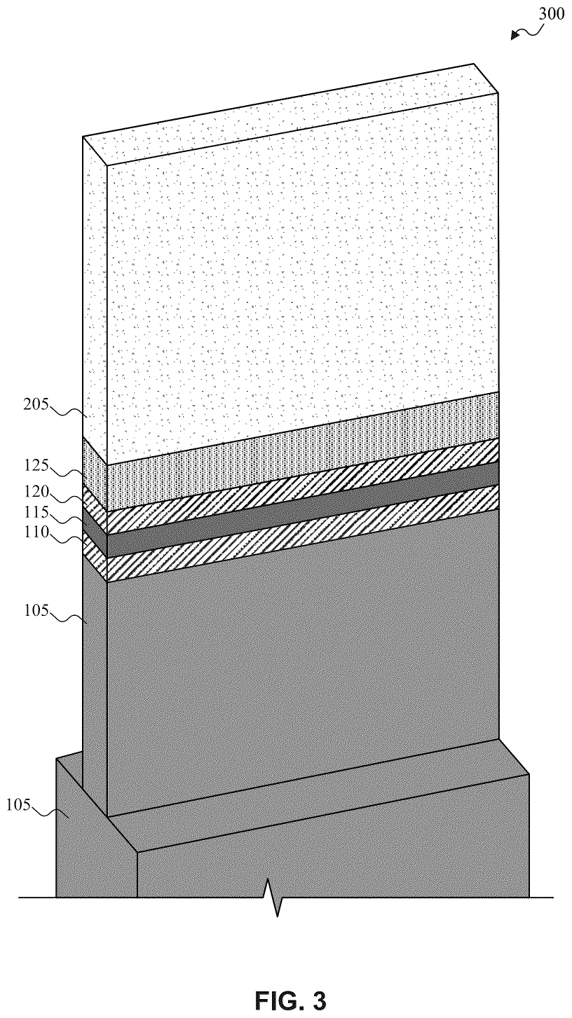

FIG. 3 illustrates an example stack 300 in accordance with one or more implementations as described herein.

Referring to FIG. 3, in some examples, stack 300 may depict layers of a semiconductor device (e.g., a semiconductor stack of a transistor). In the illustrated example, stack 300 may include substrate 105, semiconductor alloy 110, semiconductor 115, semiconductor alloy 120, dielectric 125, and mask 205. In some cases, a portion of stack 300 (e.g., a portion of stack 200) may be removed. In the systems and methods described herein, portions of a stack (e.g., at least a portion of at least one layer) may be removed by etching (e.g., dry etching, wet etching, ashing, etc. In some cases, chemicals may remove at least a portion of a layer. In some cases, gases may be used to remove at least a portion of a layer (e.g., ashing). As shown, a portion of substrate 105, semiconductor alloy 110, semiconductor 115, semiconductor alloy 120, dielectric 125, and mask 205 may be etched to form a fin of stack 300 (e.g., form one or more fins, fins of stack 300). In some cases, the compressive stress in the semiconductor alloy 110 and/or semiconductor alloy 120 (e.g., in SiGe layers) may be relaxed based on the fin etch, resulting in a tensile stress in semiconductor 115 (e.g., in the Si channel layer of an NMOS design). In some cases, a Si channel of a transistor may be based on the fin of stack 300. Thus, the fin of stack 300 may be referred to as a channel structure. Although a line is shown between a base portion of substrate 105 and a fin portion of substrate 105, the base portion and the fin portion of substrate 105 of FIG. 3 (e.g., and other figures) may be contiguous as shown in FIGS. 1 and 2,

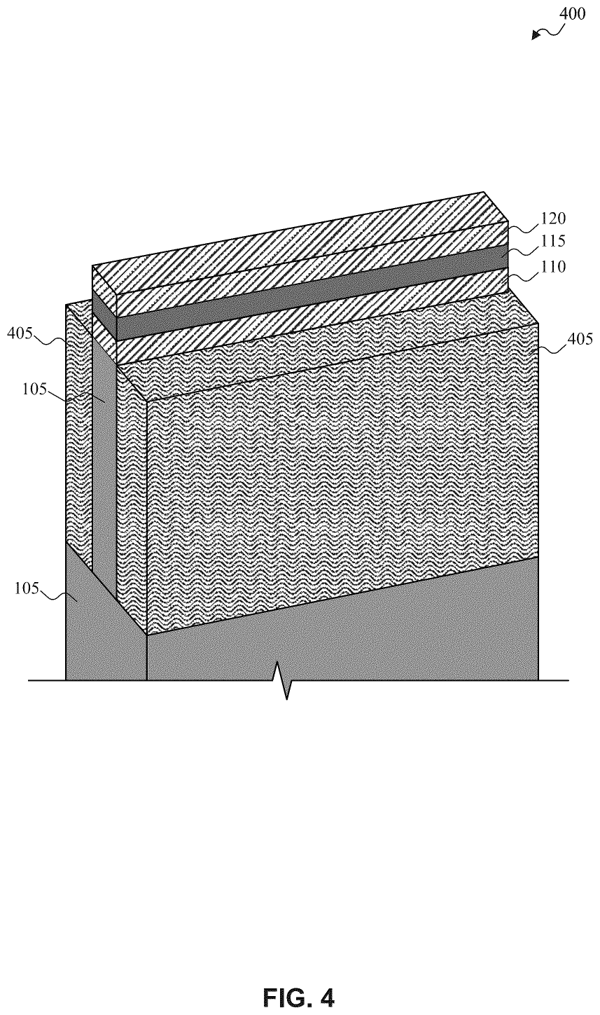

FIG. 4 illustrates an example stack 400 in accordance with one or more implementations as described herein.

Referring to FIG. 4, in some examples, stack 400 may depict layers of a semiconductor device (e.g., a semiconductor stack of a transistor). In the illustrated example, stack 400 may include substrate 105, semiconductor alloy 110, semiconductor 115, semiconductor alloy 120, and shallow trench isolation (STI) 405. Shallow trench isolation (STI), may be referred to as box isolation. STI may include an IC feature that prevents electric current leakage between adjacent semiconductor device components.

In some cases, a portion of stack 300 may be removed (e.g., via etching, dry etching, wet etching, etc.). As shown, a portion of stack 400 (e.g., a portion of stack 300) may be removed. For example, dielectric 125 and mask 205 may be removed (e.g., via etching). As shown, STI 405 may be added to stack 400. In the illustrated example, a top surface of STI 405 may come up to or relatively near a bottom surface of semiconductor alloy 110. As shown, an inside surface of STI 405 may be adjacent to an outside surface of substrate 105 (e.g., a fin portion of substrate 105). In some cases, a relatively low or insignificant change in the stress profile of semiconductor 115 (e.g., Si channel region) may occur as result of adding STI 405.

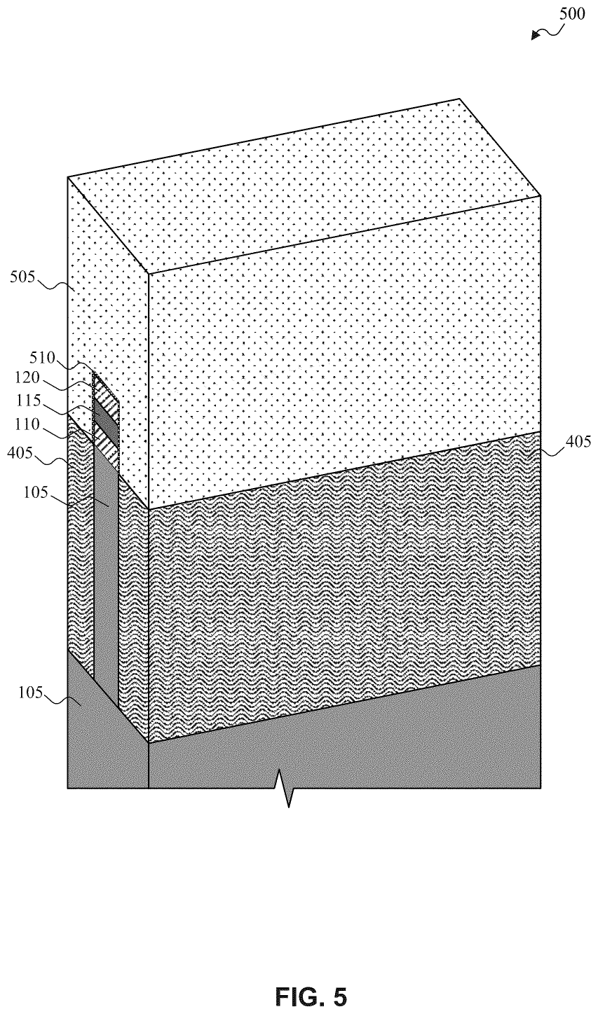

FIG. 5 illustrates an example stack 500 in accordance with one or more implementations as described herein.

Referring to FIG. 5, in some examples, stack 500 may depict layers of a semiconductor device (e.g., a semiconductor stack of a transistor). In the illustrated example, stack 500 may include substrate 105, semiconductor alloy 110, semiconductor 115, semiconductor alloy 120, STI 405, dummy gate 505, and oxide layer 510. In some cases, dummy gate 505 may include a semiconductor (e.g., polysilicon). Polysilicon (e.g., polycrystalline Si) may include a metallurgical grade or high-purity form of Si based on a chemical purification process. In some cases, a relatively low or insignificant change in the stress profile of semiconductor 115 (e.g., Si channel region) may occur as result of adding dummy gate 505. In some cases, oxide layer 510 may include a dielectric (e.g., Si oxide, Si nitride, etc.). As shown, oxide layer 510 may be deposited over semiconductor alloy 110, semiconductor 115, semiconductor alloy 120 (e.g., before depositing dummy gate 505). As shown, dummy gate 505 (e.g., polysilicon) may be deposited over a surface of semiconductor alloy 120 and/or over a surface of STI 405 (e.g., over a first surface and a second surface of STI 405). As shown, dummy gate 505 may encapsulate semiconductor alloy 110, semiconductor 115, and semiconductor alloy 120.

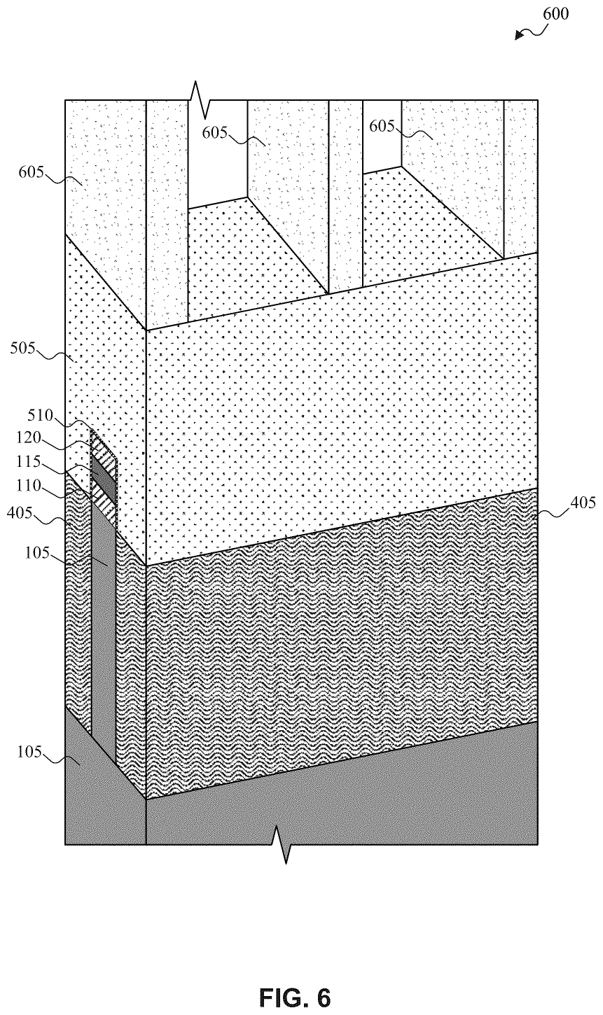

FIG. 6 illustrates an example stack 600 in accordance with one or more implementations as described herein.

Referring to FIG. 6, in some examples, stack 600 may depict layers of a semiconductor device (e.g., a semiconductor stack of a transistor). In the illustrated example, stack 600 may include substrate 105, semiconductor alloy 110, semiconductor 115, semiconductor alloy 120, STI 405, dummy gate 505, oxide layer 510, and mask 605. In some cases, mask 605 may include a photoresist mask. In some examples, mask 605 may be deposited on dummy gate 505 (e.g., a continuous layer of mask 605). In some cases, mask 605 may be etched to form one or more fins of mask 605, as shown. As shown, stack 600 may include fins of mask 605. In some cases, a relatively low or insignificant change in the stress profile of semiconductor 115 (e.g., Si channel region) may occur as result of adding and/or etching mask 605.

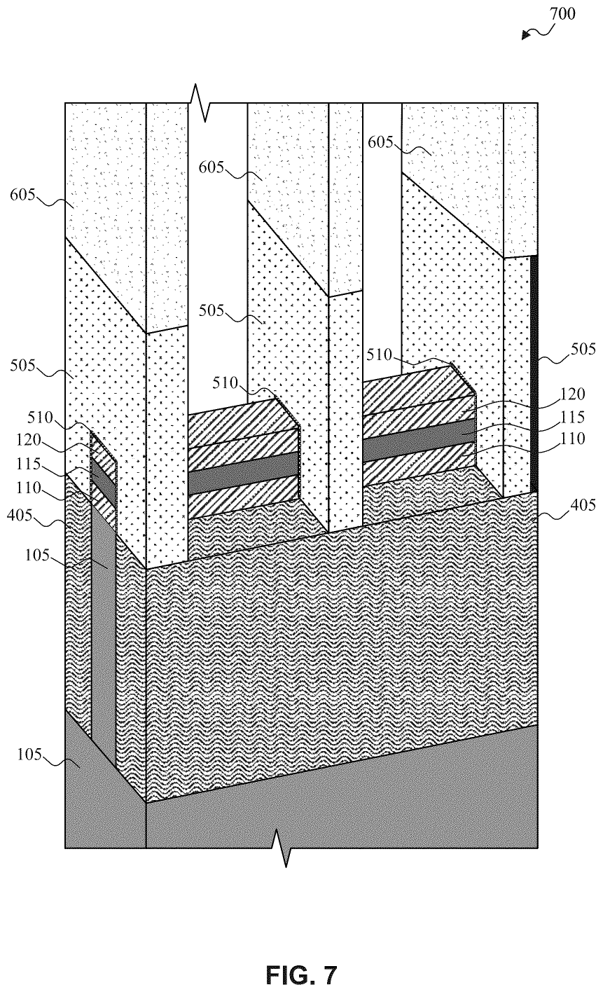

FIG. 7 illustrates an example stack 700 in accordance with one or more implementations as described herein.

Referring to FIG. 7, in some examples, stack 700 may depict layers of a semiconductor device (e.g., a semiconductor stack of a transistor). In the illustrated example, stack 700 may include substrate 105, semiconductor alloy 110, semiconductor 115, semiconductor alloy 120, STI 405, dummy gate 505, oxide layer 510, and mask 605. As shown, one or more etching processes may be applied to stack 700 (e.g., to stack 600) to form fins in mask 605 and fins in dummy gate 505. As shown, the etching process may expose portions of semiconductor alloy 110, semiconductor 115, and semiconductor alloy 120 between the fins of dummy gate 505 and mask 605. As shown, the fins of dummy gate 505 and mask 605 (e.g., fins of stack 700) may be formed to be transverse (e.g., orthogonal, at or relatively near 90 degrees) to the fin of stack 300 that is formed by etching a portion of substrate 105, semiconductor alloy 110, semiconductor 115, and semiconductor alloy 120.

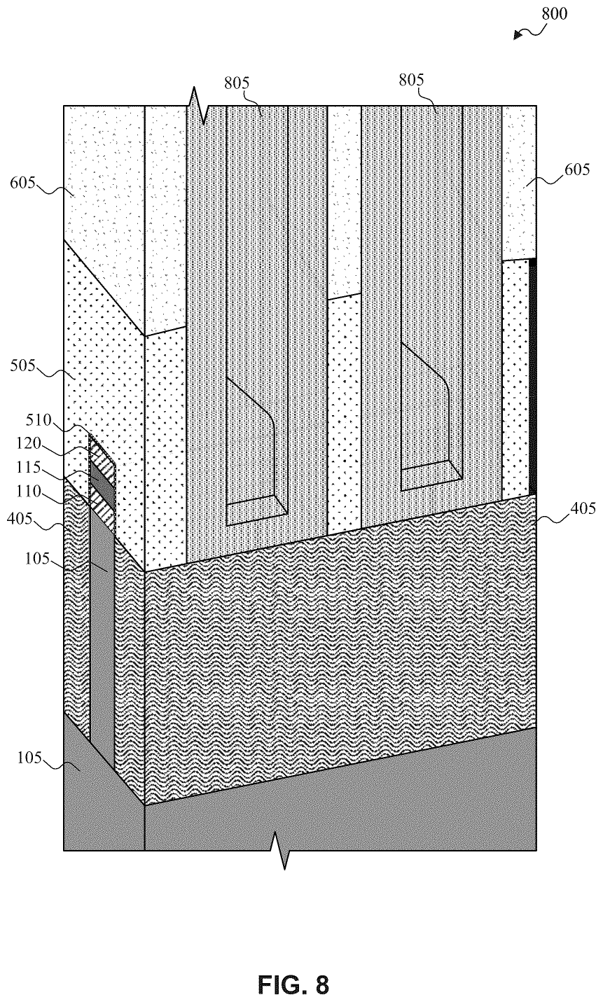

FIG. 8 illustrates an example stack 800 in accordance with one or more implementations as described herein.

Referring to FIG. 8, in some examples, stack 800 may depict layers of a semiconductor device (e.g., a semiconductor stack of a transistor). In the illustrated example, stack 800 may include substrate 105, semiconductor alloy 110, semiconductor 115, semiconductor alloy 120, STI 405, dummy gate 505, oxide layer 510, mask 605 (e.g., fins of dummy gate 505 and mask 605), and gate spacer 805. In some cases, gate spacers may be referred to as sidewalls. Gate spacers may insulate source/drain EPI and the source/drain metal contacts from the gate of a transistor.

In some cases, gate spacer 805 may be deposited on stack 800 (e.g., on stack 700). In the illustrated example, gate spacer 805 may be deposited between the fins of dummy gate 505 and mask 605 (e.g., between the fins of stack 700). As shown, gate spacer 805 may be deposited over the portions of semiconductor alloy 110, semiconductor 115, and semiconductor alloy 120 that is exposed between the fins of dummy gate 505 based on the etching process of stack 700. As shown, gate spacer 805 may form sidewalls adjacent to the fins of dummy gate 505 and mask 605. In some cases, a relatively low or insignificant change in the stress profile of semiconductor 115 (e.g., Si channel region) may occur as result of adding gate spacer 805.

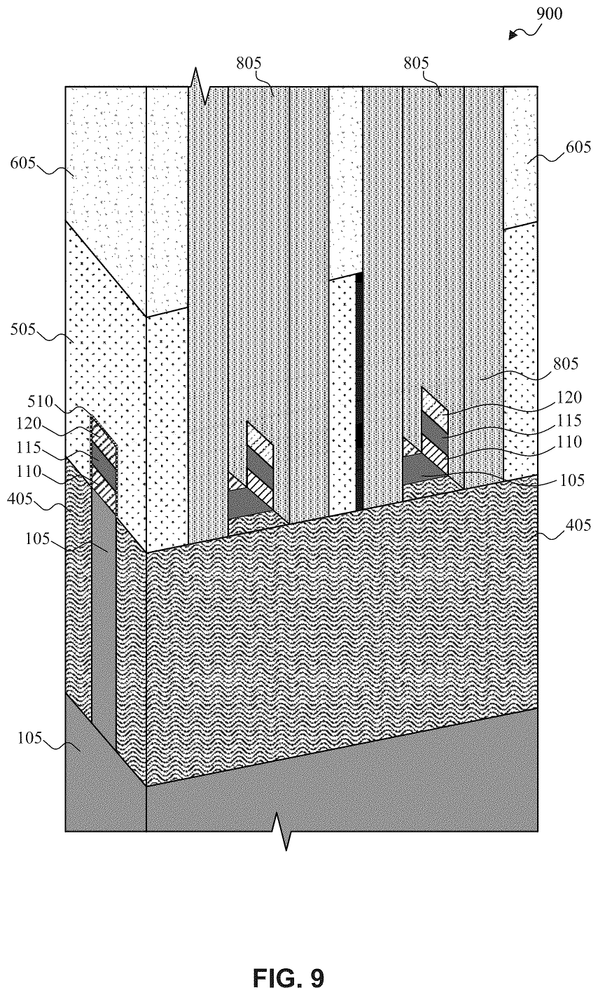

FIG. 9 illustrates an example stack 900 in accordance with one or more implementations as described herein.

Referring to FIG. 9, in some examples, stack 900 may depict layers of a semiconductor device (e.g., a semiconductor stack of a transistor). In the illustrated example, stack 900 may include substrate 105, segments of semiconductor alloy 110, segments of semiconductor 115, segments of semiconductor alloy 120, STI 405, and fins that include dummy gate 505, oxide layer 510, mask 605 (e.g., fins of dummy gate 505 and mask 605), and sidewalls of gate spacer 805.

In some examples, portions of gate spacer 805, semiconductor alloy 110, semiconductor 115, and/or semiconductor alloy 120 may be etched away. In the illustrated example, portions of gate spacer 805 between the fins of stack 900 and over semiconductor alloy 110, semiconductor 115, and semiconductor alloy 120 may be etched away. In the illustrated example, the fins of stack 900 may include the depicted fins of dummy gate 505 and mask 605 together with the sidewalls of gate spacer 805. As shown, portions of semiconductor alloy 110, semiconductor 115, and semiconductor alloy 120 between the fins of stack 900 may be etched away. Accordingly, portions of semiconductor alloy 110, semiconductor 115, and semiconductor alloy 120 may remain within or under the fins of stack 900 (e.g., embedded in the fins of stack 900).

In some cases, etching the portions of gate spacer 805 and the portions of semiconductor alloy 110, semiconductor 115, and semiconductor alloy 120 between the fins of stack 900 may reduce the compressive stress in the semiconductor alloy 110 and/or semiconductor alloy 120 (e.g., in SiGe layers). In some cases, reducing the compressive stress in the semiconductor alloy 110 and/or semiconductor alloy 120 results in increased tensile stress in semiconductor 115 (e.g., in the Si channel of an NMOS design).

As shown, a gap or open area may be formed between the sidewalls of gate spacer 805 based on etching the portions of gate spacer 805 and the portions of semiconductor alloy 110, semiconductor 115, and semiconductor alloy 120 between the fins of stack 900. In some cases, the gap between the sidewalls of gate spacer 805 may be associated with a source region and/or a drain region of a transistor. The etching process used to create this gap may result in a change in stress in the channel, as material removal can alter the mechanical properties of the surrounding structures. In some cases, an area filled with dummy gate 505 may be associated with a gate region of a transistor.

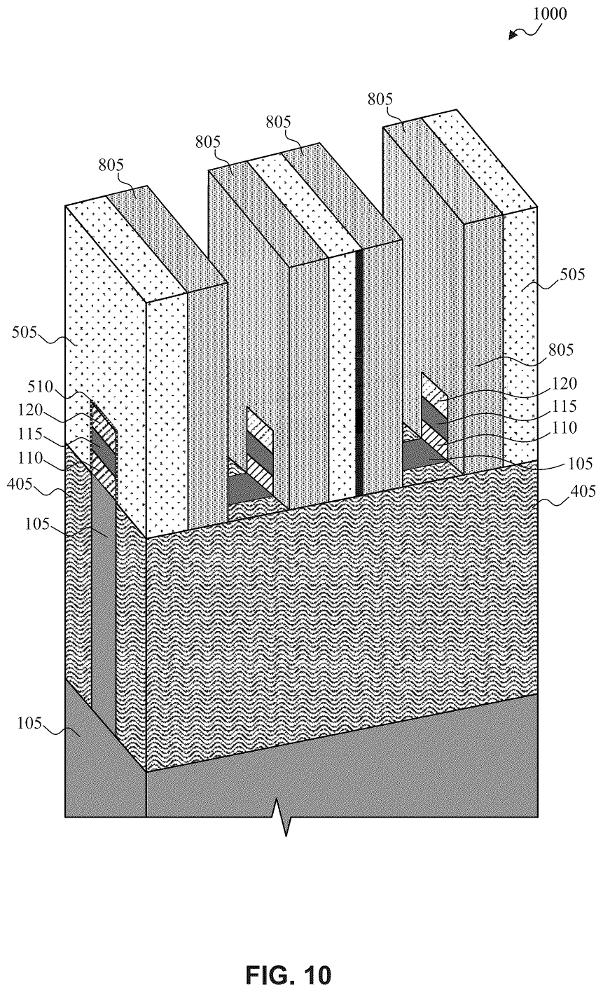

FIG. 10 illustrates an example stack 1000 in accordance with one or more implementations as described herein.

Referring to FIG. 10, in some examples, stack 1000 may depict layers of a semiconductor device (e.g., a semiconductor stack of a transistor). In the illustrated example, stack 1000 may include substrate 105, segments of semiconductor alloy 110, segments of semiconductor 115, segments of semiconductor alloy 120, STI 405, dummy gate 505, oxide layer 510, and sidewalls of gate spacer 805 (e.g., fins of dummy gate 505 and gate spacer 805).

In the illustrated example, mask 605 and a portion of the sidewalls of gate spacer 805 may be removed from stack 1000 (e.g., etched from stack 900), resulting in the depicted fins. As shown, FIG. 10 depicts three fins that include a portion of a first fin, a second fin, and a portion of a third fin. In some cases, FIG. 10 may depict three fins of a repeating pattern of 3 or more fins. A portion of the first fin is removed from view (e.g., a portion of the first fin sheared for illustration) to show the structure of the segments of semiconductor alloy 110, segments of semiconductor 115, and segments of semiconductor alloy 120 embedded within a given fin. As shown, the depicted first fin includes dummy gate 505 between sidewalls of gate spacer 805, where a first sidewall of gate spacer 805 is depicted, while the other sidewall of gate spacer 805 and a portion of dummy gate 505 are not shown for the first fin. The second fin depicts dummy gate 505 between a second sidewall of gate spacer 805 and a third sidewall of gate spacer 805. Thus, the second fin depicts a whole fin. The third fin depicts a fourth sidewall of gate spacer 805 and a portion of dummy gate 505, while the other sidewall of gate spacer 805 and a portion of dummy gate 505 are not shown for the third fin to show the contacted poly pitch (CPP), or transistor gate pitch, of stack 1000.

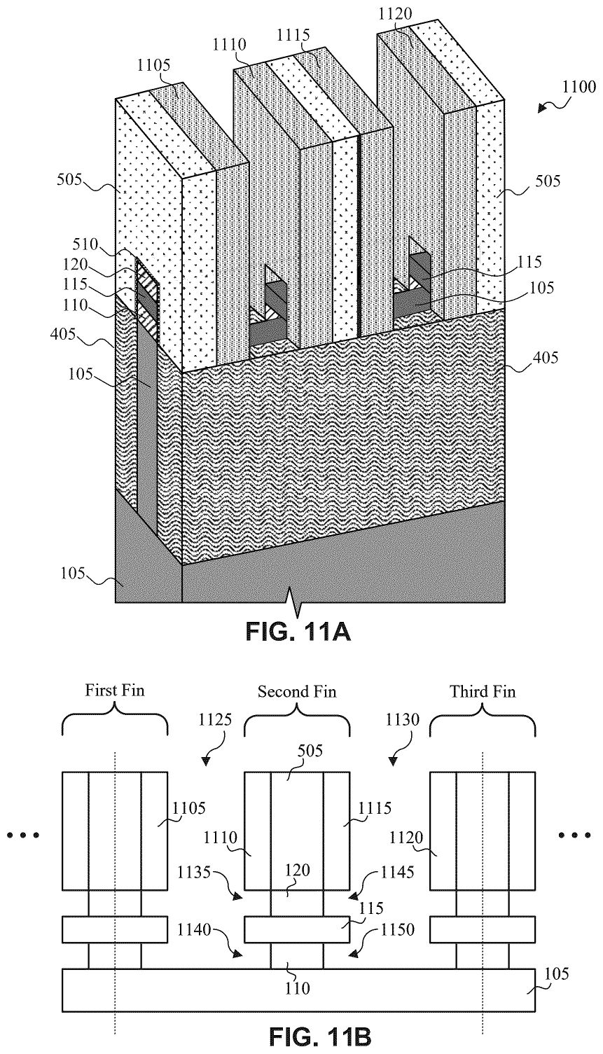

FIG. 11A illustrates an example stack 1100 in accordance with one or more implementations as described herein.

Referring to FIG. 11A, in some examples, stack 1100 may depict layers of a semiconductor device (e.g., a semiconductor stack of a transistor). In the illustrated example, stack 1100 may include substrate 105, segments of semiconductor alloy 110, segments of semiconductor 115, segments of semiconductor alloy 120, STI 405, dummy gate 505, oxide layer 510, sidewalls of gate spacer 805 (e.g., fins of dummy gate 505 and gate spacer 805). Stack 1100 also depicts multiple sidewalls of gate spacer 805. As shown, the depicted sidewalls include first sidewall 1105, second sidewall 1110, third sidewall 1115, and fourth sidewall 1120 (e.g., sidewalls of gate spacer 805). As shown, a first portion of dummy gate 505 (e.g., sheared portion) is depicted adjacent to first sidewall 1105, first gap 1125 is depicted between first sidewall 1105 and second sidewall 1110, dummy gate 505 (e.g., a whole portion of dummy gate 505) is depicted between second sidewall 1110 and third sidewall 1115, second gap 1130 is depicted between third sidewall 1115 and fourth sidewall 1120, and a second portion of dummy gate 505 (e.g., sheared portion) is depicted adjacent to fourth sidewall 1120.

In the illustrated example, at least a portion of a segment of semiconductor alloy 110 and/or a segment of semiconductor alloy 120 may be removed from an outside edge of a given fin. For example, a portion of a segment of semiconductor alloy 110 and/or a segment of semiconductor alloy 120 that is under or within first sidewall 1105, second sidewall 1110, third sidewall 1115, and/or fourth sidewall 1120 may be removed.

In the illustrated example, one or more cavity formations may be formed in stack 1100. In some examples, portions of the segments of semiconductor alloy 110 and segments of semiconductor alloy 120 may be removed at the outside edges of a given fin. For example, portions of semiconductor alloy 110 and semiconductor alloy 120 under a given sidewall of gate spacer 805 may be removed, resulting in cavity formations in stack 1100, In some cases, the cavity formations may result in a reduction in compressive stress in the segments of semiconductor alloy 110 and segments of semiconductor alloy 120. In some cases, reducing compressive stress at the cavity formations may result in an increase in tensile stress in the segments of semiconductor 115 (e.g., in the segments of the Si channel based on an NMOS design) within a given fin.

FIG. 11B illustrates a side view of stack 1100 in accordance with one or more implementations as described herein.

Referring to FIG. 11B, in some examples, FIG. 11B may depict a side view of stack 1100 based on the three-dimensional view of stack 1100 of FIG. 11A. As shown, the side view of stack 1100 in FIG. 11B depicts a first fin, a second fin, and a third fin. The dotted lines depict where the portion of the first fin and the portion of the third fin are removed from view in FIG. 11A. As shown, first fin includes first sidewall 1105 (e.g., and another sidewall not shown in FIG. 11A); second fin includes second sidewall 1110, dummy gate 505, oxide layer 510, and third sidewall 1115; and the depicted third fin includes fourth sidewall 1120 (e.g., and another sidewall not shown in FIG. 11A).

In the illustrated example, at least a portion of a segment of semiconductor alloy 110 and/or a segment of semiconductor alloy 120 may be removed from an outside edge of a given fin. For example, a portion of a segment of semiconductor alloy 110 and/or a segment of semiconductor alloy 120 that is under or within second sidewall 1110 may be removed, resulting in cavity 1135 and cavity 1140. As shown, a portion of a segment of semiconductor alloy 110 and/or a segment of semiconductor alloy 120 that is under or within third sidewall 1115 may be removed, resulting in cavity 1145 and cavity 1150. As shown, a segment of semiconductor 115 remains within second fin and runs from one edge to the other edge of the second fin. Cavity 1135, cavity 1140, cavity 1145, and cavity 1150 may result in a reduction in compressive stress in the respective segments of semiconductor alloy 110 and segments of semiconductor alloy 120. In some cases, reducing compressive stress at the cavity formations may result in an increase in tensile stress in the segments of semiconductor 115 (e.g., in the segments of semiconductor 115 of the second fin based on an NMOS design).

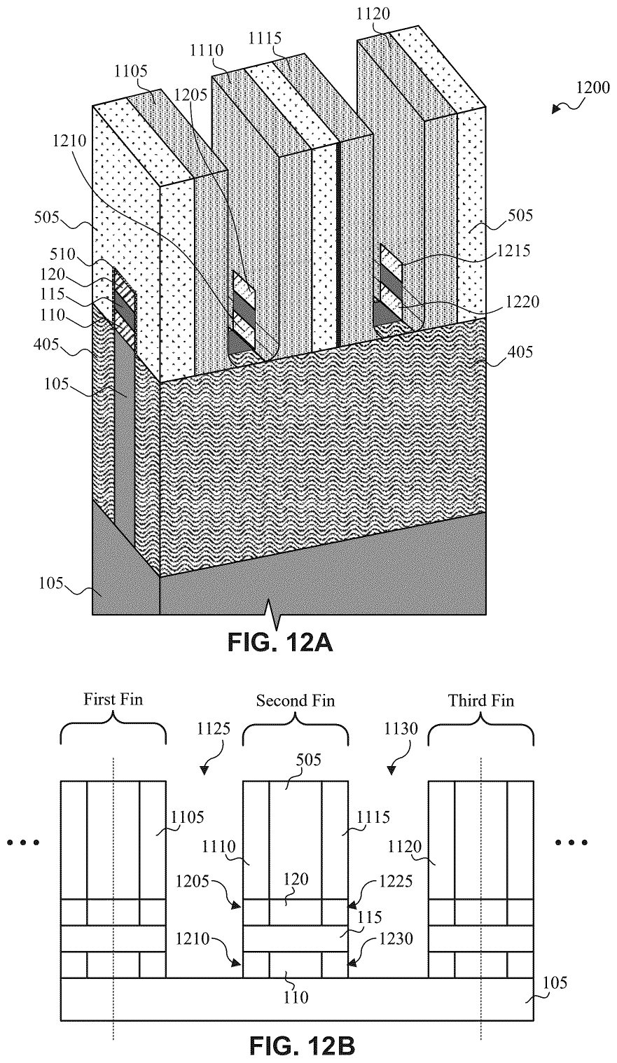

FIG. 12A illustrates an example stack 1200 in accordance with one or more implementations as described herein.

Referring to FIG. 12A, in some examples, stack 1200 may depict layers of a semiconductor device (e.g., a semiconductor stack of a transistor). In the illustrated example, stack 1200 may include substrate 105, segments of semiconductor alloy 110, segments of semiconductor 115, segments of semiconductor alloy 120, STI 405, dummy gate 505, oxide layer 510, sidewalls of gate spacer 805 (e.g., fins of dummy gate 505 and gate spacer 805).

In the illustrated example, material may be deposited on stack 1200 that fills in the cavity formations (e.g., fills in the cavity formations of stack 1100). The material may be referred to as an inner spacer (e.g., inner spacer 1205, inner spacer 1210, inner spacer 1215, inner spacer 1220). In some cases, the inner spacer may include a dielectric material.

FIG. 12B illustrates a side view of stack 1200 in accordance with one or more implementations as described herein.

Referring to FIG. 12B, in some examples, FIG. 12B may depict a side view of stack 1200 based on the three-dimensional view of stack 1200 of FIG. 12A. As shown, the side view of stack 1200 in FIG. 12B depicts a first fin, a second fin, and a third fin. The dotted lines depict where the portion of the first fin and the portion of the third fin are removed from view in FIG. 12A. As shown, first fin includes first sidewall 1105 (e.g., and another sidewall not shown in FIG. 12A); second fin includes second sidewall 1110, dummy gate 505, oxide layer 510, and third sidewall 1115; and the depicted third fin includes fourth sidewall 1120 (e.g., and another sidewall not shown in FIG. 12A).

In the illustrated example, a first cavity formation of the second fin may be filled in with inner spacer 1205, a second cavity formation of the second fin may be filled in with inner spacer 1210, a third cavity formation of the second fin may be filled in with inner spacer 1225, and a fourth cavity formation of the second fin may be filled in with inner spacer 1230. As shown, one or more cavity formations of the first fin and/or the third find may be filled in with respective inner spacers.

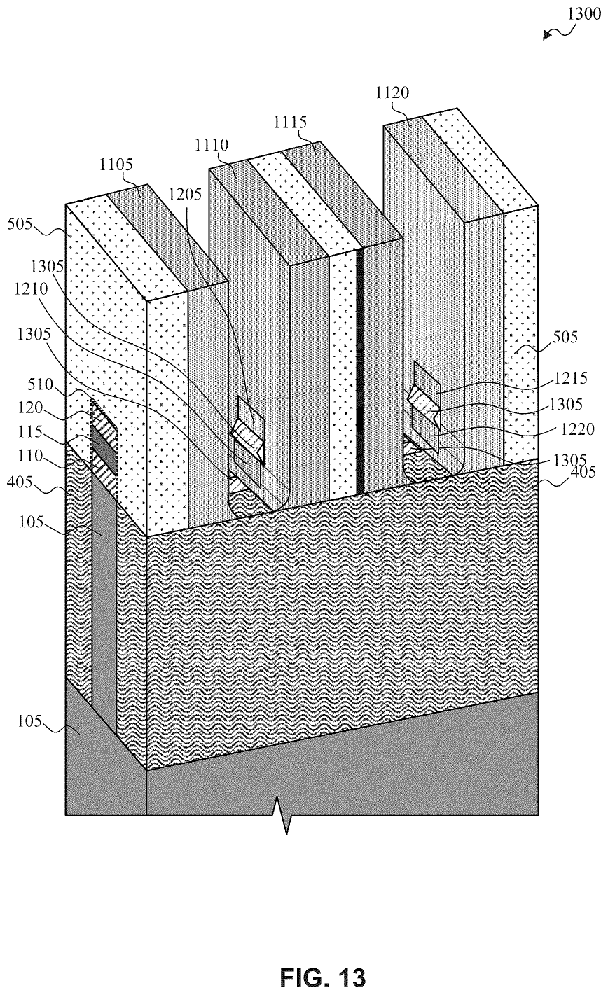

FIG. 13 illustrates an example stack 1300 in accordance with one or more implementations as described herein.

Referring to FIG. 13, in some examples, stack 1300 may depict layers of a semiconductor device (e.g., a semiconductor stack of a transistor). In the illustrated example, stack 1300 may include substrate 105, segments of semiconductor alloy 110, segments of semiconductor 115, segments of semiconductor alloy 120, STI 405, dummy gate 505, oxide layer 510, sidewalls of gate spacer 805 (e.g., fins of dummy gate 505 and gate spacer 805), inner spacer 1205, inner spacer 1210, inner spacer 1215, inner spacer 1220, and EPI film 1305.

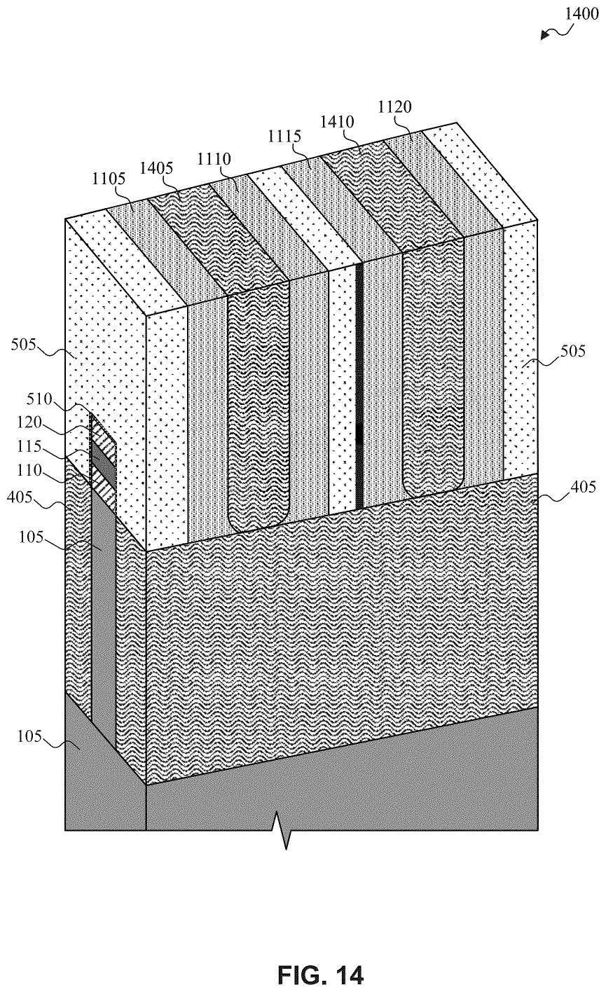

In the illustrated example, EPI film 1305 may be grown between the fins of dummy gate 505 and gate spacer 805 (e.g., in the S/D regions of stack 1300). As shown, one or more portions of EPI film 1305 may be deposited between first sidewall 1105 and second sidewall 1110, and/or deposited between third sidewall 1115 and fourth sidewall 1120. The EPI film 1305 may be deposited after a stressor material 1405 is deposited (as shown in FIG. 14, below). In some cases, EPI film 1305 may include SiGe for PMOS, Si or SiC for NMOS. In some cases, EPI film 1305 may not be allowed to merge. For example, the systems and methods may include a process where EPI film 1305 is not allowed to merge. As a result, a relatively insignificant change in the stress profile of the channel region may occur as a result of depositing unmerged EPI film 1305.

FIG. 14 illustrates an example stack 1400 in accordance with one or more implementations as described herein.

Referring to FIG. 14, in some examples, stack 1400 may depict layers of a semiconductor device (e.g., a semiconductor stack of a transistor). In the illustrated example, stack 1400 may include substrate 105, segments of semiconductor alloy 110, segments of semiconductor 115, segments of semiconductor alloy 120, STI 405, dummy gate 505, oxide layer 510, sidewalls of gate spacer 805 (e.g., fins of dummy gate 505 and gate spacer 805), stressor material 1405, and stressor material 1410. In some cases, portions of inner spacer 1205, inner spacer 1210, inner spacer 1215, inner spacer 1220, inner spacer 1225, inner spacer 1230, and/or EPI film 1305 may be embedded in or under sidewalls of gate spacer 805, stressor material 1405, and/or stressor material 1410.

In the illustrated example, a stressor material (e.g., stressor material 1405 and stressor material 1410) may be deposited between the fins of dummy gate 505 and gate spacer 805 (e.g., in the S/D regions of stack 1400) before the EPI film 1305 has been deposited. As shown, stressor material 1405 may be deposited between first sidewall 1105 and second sidewall 1110, and/or stressor material 1410 may be deposited between third sidewall 1115 and fourth sidewall 1120.

In some examples, before depositing EPI film 1305, either compressive (for PMOS) or tensile (for NMOS) stressor material 1405 and stressor material 1410 may be added to the source region and the drain region of stack 1400. In some cases, the source region may be between first sidewall 1105 and second sidewall 1110, and the drain region may be between third sidewall 1115 and fourth sidewall 1120. In some cases, the drain region may be between first sidewall 1105 and second sidewall 1110, and the source region may be between third sidewall 1115 and fourth sidewall 1120. Depositing compressive (or tensile) stressor material 1405 and stressor material 1410 may apply compressive (or tensile) stress at the S/D regions. For example, depositing stressor material with tensile stress at the S/D regions may increase the tensile stress at the segments of semiconductor 115 (e.g., at the Si channel region of stack 1400 based on an NMOS design). In some cases, stressor material 1405 and/or stressor material 1410 may include a dielectric, a metal, or a material that has intrinsic stress. In other words, the stressor material 1405 and/or 1410 can be any material with an intrinsic stress greater than a predetermined level. In some cases, stressor material 1405 and stressor material 1410 may include at least one of aluminum oxide, moly-oxide, hafnium oxide, etc. Accordingly, the systems and methods provide mechanisms to add stress in an Si channel of a transistor and efficiently transfer stress from stressor materials (e.g., stressor material 1405 and stressor material 1410) to the Si channel. The systems and methods of inducing stress provide an increase in the drive current of a given transistor. Stressor material 1405 and/or stressor material 1410 may be deposited before EPI film 1305 is deposited (e.g. before EPI film crystals grow until touching) for maximal stress transfer from the stressor material 1405 and/or stressor material 1410 to the semiconductor 115.

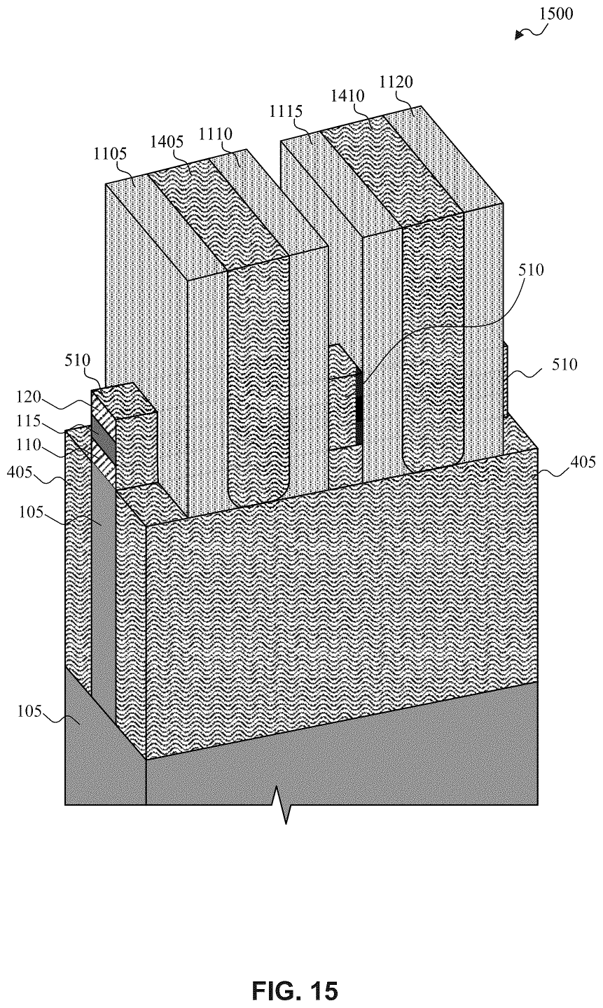

FIG. 15 illustrates an example stack 1500 in accordance with one or more implementations as described herein.

Referring to FIG. 15, in some examples, stack 1500 may depict layers of a semiconductor device (e.g., a semiconductor stack of a transistor). In the illustrated example, stack 1500 may include substrate 105, segments of semiconductor alloy 110, segments of semiconductor 115, segments of semiconductor alloy 120, STI 405, oxide layer 510, sidewalls of gate spacer 805, stressor material 1405, and stressor material 1410. In some cases, portions of inner spacer 1205, inner spacer 1210, inner spacer 1215, inner spacer 1220, inner spacer 1225, inner spacer 1230, and/or EPI film 1305 may be embedded in or under sidewalls of gate spacer 805, stressor material 1405, and/or stressor material 1410.

In the illustrated example, the fins of dummy gate 505 may be removed (e.g., via etching, removed from stack 1400). As shown, the sidewalls of gate spacer 805 may remain based on removing the fins of dummy gate 505. Stack 1500 may include one or more fins, where a given fin includes a first sidewall of gate spacer 805, stressor material (e.g., stressor material 1405, stressor material 1410), and a second sidewall of gate spacer 805. As shown, removing the fins of dummy gate 505 exposes the segments of semiconductor alloy 110, segments of semiconductor 115, segments of semiconductor alloy 120 that were embedded in the fins of dummy gate 505. As shown, the segments of semiconductor alloy 110, segments of semiconductor 115, segments of semiconductor alloy 120 may be covered in oxide layer 510. Removing the fins of dummy gate 505 further increases the tensile stress at the segments of semiconductor 115 (e.g., at the Si channel based on an NMOS design). In some cases, removing the fins of dummy gate 505 decreases a compressive stress on the segments of semiconductor 115, thereby increasing the tensile stress at the segments of semiconductor 115.

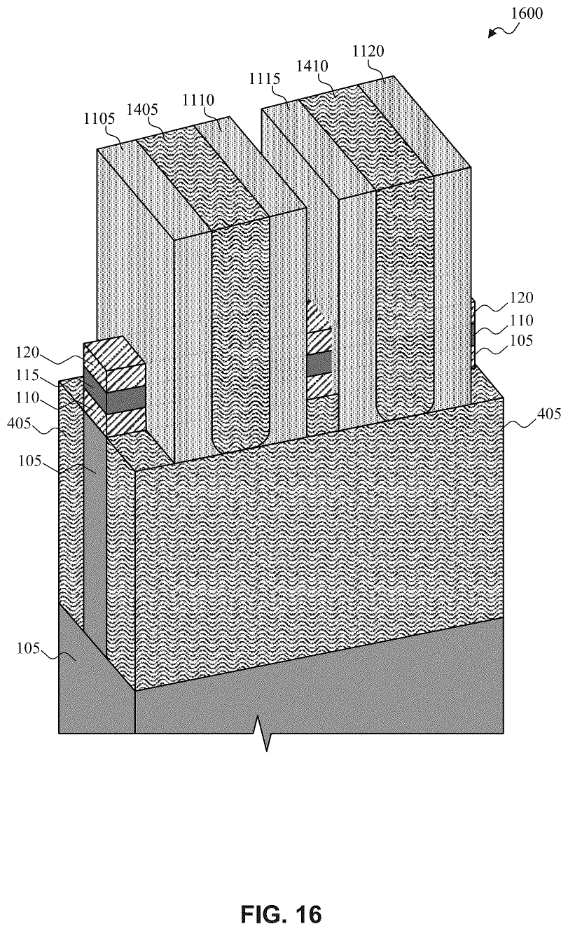

FIG. 16 illustrates an example stack 1600 in accordance with one or more implementations as described herein.

Referring to FIG. 16, in some examples, stack 1600 may depict layers of a semiconductor device (e.g., a semiconductor stack of a transistor). In the illustrated example, stack 1600 may include substrate 105, segments of semiconductor alloy 110, segments of semiconductor 115, segments of semiconductor alloy 120, STI 405, sidewalls of gate spacer 805, stressor material 1405, and stressor material 1410. In some cases, portions of inner spacer 1205, inner spacer 1210, inner spacer 1215, inner spacer 1220, inner spacer 1225, inner spacer 1230, and/or EPI film 1305 may be embedded in or under sidewalls of gate spacer 805, stressor material 1405, and/or stressor material 1410. As shown, stack 1600 may include one or more fins (e.g., fins of stack 1600), where a given fin includes a first sidewall of gate spacer 805, stressor material (e.g., stressor material 1405, stressor material 1410), and a second sidewall of gate spacer 805.

In the illustrated example, oxide layer 510 (e.g., of stack 1500) may be removed, exposing the segments of semiconductor alloy 110, segments of semiconductor 115, and segments of semiconductor alloy 120 between the fins of stack 1600. In some examples, removing the fins of dummy gate 505 further increases the tensile stress at the segments of semiconductor 115 (e.g., at the Si channel based on an NMOS design).

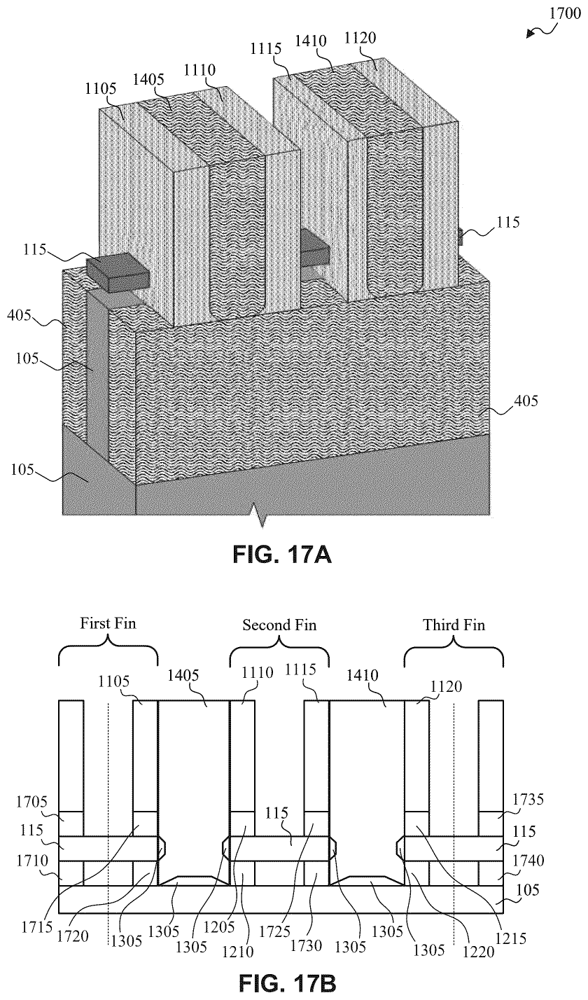

FIG. 17A illustrates an example stack 1700 in accordance with one or more implementations as described herein.

Referring to FIG. 17A, in some examples, stack 1700 may depict layers of a semiconductor device (e.g., a semiconductor stack of a transistor). In the illustrated example, stack 1700 may include substrate 105, segments of semiconductor 115, STI 405, sidewalls of gate spacer 805, stressor material 1405, and stressor material 1410. In some cases, portions of inner spacer 1205, inner spacer 1210, inner spacer 1215, inner spacer 1220, inner spacer 1225, inner spacer 1230, and/or EPI film 1305 may be embedded in or under sidewalls of gate spacer 805, stressor material 1405, and/or stressor material 1410. As shown, stack 1700 may include one or more fins (e.g., fins of stack 1700), where a given fin includes a first sidewall of gate spacer 805, stressor material (e.g., stressor material 1405, stressor material 1410), and a second sidewall of gate spacer 805.

In the illustrated example, segments of semiconductor alloy 110 and/or segments of semiconductor alloy 120 may be removed from stack 1700 (e.g., from stack 1600 based on etching), leaving segments of semiconductor 115. Based on removing segments of semiconductor alloy 110 and/or segments of semiconductor alloy 120, a portion of inner spacer (e.g., inner spacer 1205, inner spacer 1210, inner spacer 1215, and/or inner spacer 1220) may be exposed above or below the segments of semiconductor 115, within a cavity of a sidewall of gate spacer 805 above or below the segments of semiconductor 115. In some examples, removing the segments of semiconductor alloy 110 and/or segments of semiconductor alloy 120 may reduce tensile stress (or increase compressive stress) in the segments of semiconductor 115 (e.g., in the Si channel).

FIG. 17B illustrates a side view of stack 1700 in accordance with one or more implementations as described herein.

Referring to FIG. 17B, in some examples, stack 1700 may depict layers of a semiconductor device (e.g., a semiconductor stack of a transistor). In the illustrated example, stack 1700 may include substrate 105, segments of semiconductor 115, sidewalls of gate spacer 805 (e.g., first sidewall 1105, second sidewall 1110, third sidewall 1115, and fourth sidewall 1120), inner spacer 1205, inner spacer 1210, inner spacer 1215, inner spacer 1220, stressor material 1405, stressor material 1410, inner spacer 1705, inner spacer 1710, inner spacer 1715, and inner spacer 1720, inner spacer 1725, and inner spacer 1730, inner spacer 1735, and inner spacer 1740. In some cases, a material of a sidewall of gate spacer 805 may be the same material as that of an inner spacer of FIG. 17B (e.g., inner spacer 1705, etc.). In some cases, portions of inner spacer 1205, inner spacer 1210, inner spacer 1215, inner spacer 1220, inner spacer 1225, and/or inner spacer 1230, may be embedded in or under sidewalls of gate spacer 805, stressor material 1405, and/or stressor material 1410. As shown, EPI film 1305 may be embedded in stressor material 1405, and/or stressor material 1410.

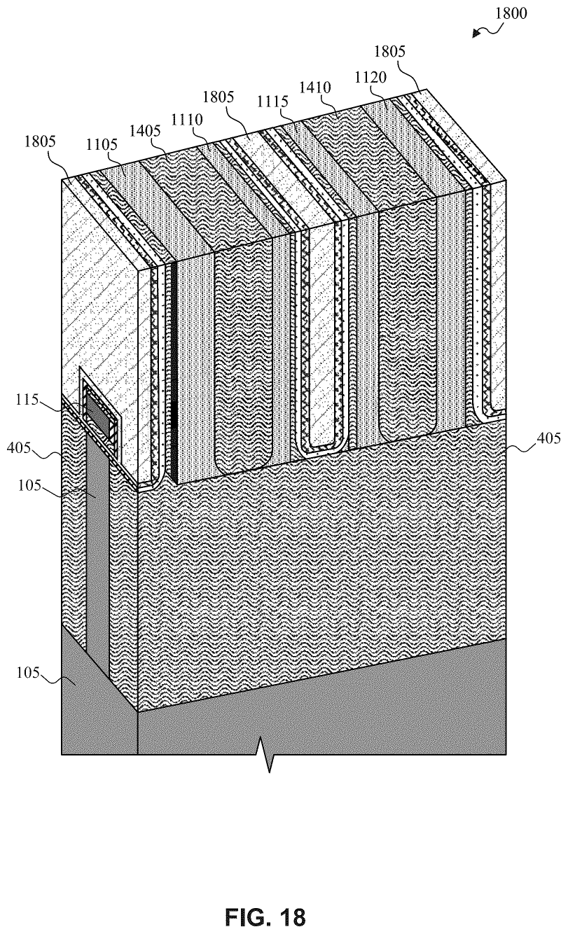

FIG. 18 illustrates an example stack 1800 in accordance with one or more implementations as described herein.

Referring to FIG. 18, in some examples, stack 1800 may depict layers of a semiconductor device (e.g., a semiconductor stack of a transistor). In the illustrated example, stack 1800 may include substrate 105, STI 405, sidewalls of gate spacer 805, second sidewall 1110, third sidewall 1115, stressor material 1405, stressor material 1410, and gate material 1805. In some cases, portions of inner spacer 1205, inner spacer 1210, inner spacer 1215, inner spacer 1220, inner spacer 1225, inner spacer 1230, and/or EPI film 1305 may be embedded in or under sidewalls of gate spacer 805, stressor material 1405, and/or stressor material 1410.

In the illustrated example, gate material 1805 may be deposited in an open space (e.g., an open space of stack 1700) between second sidewall 1110 and third sidewall 1115. As shown, additional gate material may be deposited between other or adjacent open spaces between other sidewalls of gate spacer 805. In some examples, segments of semiconductor 115 may be embedded in or under deposits of gate material 1805. In some cases, gate material 1805 may include replacement metal gate (RMG) material. In some cases, depositing gate material 1805 locks in a stress profile of the segments of semiconductor 115 (e.g., in the Si channel of stack 1800, due to high Young's modulus of gate material 1805, for example). In some cases, gate material 1805 may include an interfacial layer (e.g., Si oxide). In some cases, gate material 1805 may include a high-K material (e.g., high-K dielectric, material with high dielectric constant, hafnium oxide, etc.). In some cases, gate material 1805 may include a metal (e.g., a relatively hard material, conductive material, tungsten, etc.).

Before the metal is added (e.g., to gate material 1805), an oxide may be deposited and a high-K material (e.g., without interfacial oxide layer). In some cases, an interfacial oxide layer may be deposited on the Si channel (e.g., based on the Si oxide being grown on the Si surface using oxidation process). In some cases, the high-K material may be deposited conformally (e.g., based on atomic layer deposition). After the high-K material, a metal (e.g., tungsten) may be deposited to fill in the remaining gap. In some cases, chemical-mechanical planarization may be performed to make the top surface flat.

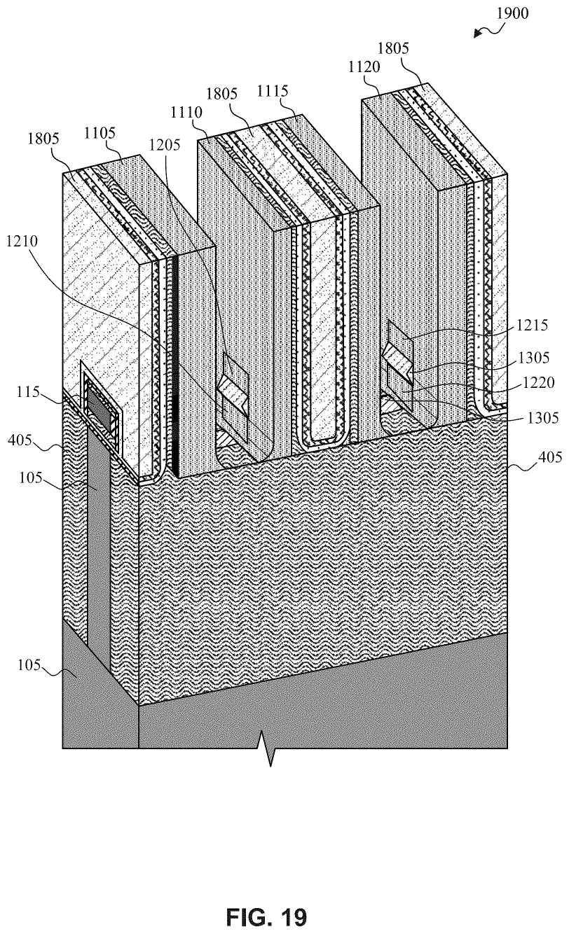

FIG. 19 illustrates an example stack 1900 in accordance with one or more implementations as described herein.

Referring to FIG. 19, in some examples, stack 1900 may depict layers of a semiconductor device (e.g., a semiconductor stack of a transistor). In the illustrated example, stack 1900 may include substrate 105, segments of semiconductor alloy 110, segments of semiconductor 115, segments of semiconductor alloy 120, STI 405, sidewalls of gate spacer 805, first sidewall 1105, second sidewall 1110, third sidewall 1115, fourth sidewall 1120, inner spacer 1205, inner spacer 1210, inner spacer 1215, inner spacer 1220, and gate material 1805. As shown, stack 1900 may include one or more fins (e.g., fins of stack 1900), where a given fin includes second sidewall 1110, gate material 1805, and third sidewall 1115. In some examples, segments of semiconductor 115 may be embedded in or under deposits of gate material 1805. Additionally, a channel may be positioned between the first sidewall 1105 and the second sidewall 110. The channel may be embedded inside a dummy gate or metal gate, and encased by semiconductor alloy layers.

In the illustrated example, stressor material 1405 and/or stressor material 1410 may be removed from stack 1900 (e.g., from stack 1800). In some cases, removing stressor material 1405 and/or stressor material 1410 may expose portions of inner spacer 1205, inner spacer 1210, inner spacer 1215, inner spacer 1220, and/or EPI film 1305. In some cases, the stress profile of the segments of semiconductor 115 (e.g., in the Si channel of stack 1800) with stressor material 1405 and/or stressor material 1410 may be maintained after removing stressor material 1405 and/or stressor material 1410. For example, based on gate material 1805 locking in the stress profile of stack 1900 (e.g., due to high Young's modulus of gate material 1805 (e.g., stiff material property)), removing stressor material 1405 and/or stressor material 1410 may not affect the stress profile (e.g., stress level is maintained in the Si channel).

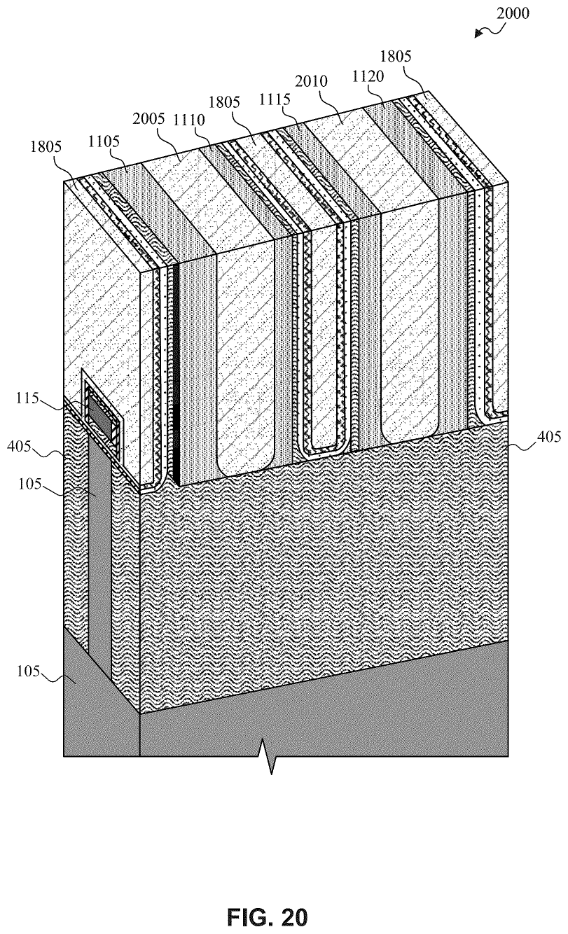

FIG. 20 illustrates an example stack 2000 in accordance with one or more implementations as described herein.

Referring to FIG. 20, in some examples, stack 2000 may depict layers of a semiconductor device (e.g., a semiconductor stack of a transistor). In the illustrated example, stack 2000 may include substrate 105, STI 405, sidewalls of gate spacer 805 (e.g., first sidewall 1105, second sidewall 1110, third sidewall 1115, fourth sidewall 1120), gate material 1805, source material 2005, and drain material 2010. In some cases, portions of inner spacer 1205, inner spacer 1210, inner spacer 1215, inner spacer 1220, inner spacer 1225, inner spacer 1230, and/or EPI film 1305 may be embedded in or under sidewalls of gate spacer 805, source material 2005, and/or drain material 2010. In some cases, segments of semiconductor 115 may be embedded in or under gate material 1805.

In the illustrated example, source material 2005 and/or drain material 2010 may be added to S/D regions of stack 2000 (e.g., to stack 1900). As shown, source material 2005 may be added between first sidewall 1105 and second sidewall 1110, and drain material 2010 may be added between third sidewall 1115 and fourth sidewall 1120. Alternatively, drain material 2010 may be added between first sidewall 1105 and second sidewall 1110, and source material 2005 may be added between third sidewall 1115 and fourth sidewall 1120. In some cases, source material 2005 and/or drain material 2010 may include a metal (e.g., a relatively hard material, conductive material, molybdenum, ruthenium, copper, tungsten, etc.). According to various embodiments disclosed herein, the S/D region may be filled with an EPI (e.g., SiGe EPI) prior to the source material 2005 and/or drain material 2010 being deposited. Therefore, the EPI structure may be embedded under (below) source material 2005 and/or drain material 2010. Based on gate material 1805 locking in the stress profile of stack 2000, adding source material 2005 and/or drain material 2010 may not affect the stress profile (e.g., stress level is maintained in the Si channel).

Based on the systems and methods described herein, multiple advantages and benefits are realized. For example, the systems and methods include applying stress in transistors based on depositing dummy stressor materials (e.g., stressor material 1405, stressor material 1410) to a source and/or drain region of a transistor before depositing an EPI film (or material) 1305. Depositing a dummy stress material to S/D regions of a transistor before depositing an EPI material improves stress transfer efficiency since the stressor material is in line with the channel (as opposed to depositing a stressor material on top of a grown EPI which may lead to less effective stress transfer) and avoids the issues of reduced stress that can occur as a result of discontinuous EPI growth. Depositing a dummy stress material to S/D regions of a transistor before depositing an EPI material provides an optimal amount of stress to an Si channel of a transistor (e.g., segments of semiconductor 115). The systems and methods described herein are applicable to any transistor structure having a discontinuous EPI film in the S/D region (e.g., MBCFETs, FinFET, Forksheet FET, 3D stacked FET, or nanosheet transistors) with an inner spacer, with BDI, and/or inner spacer and BDI.

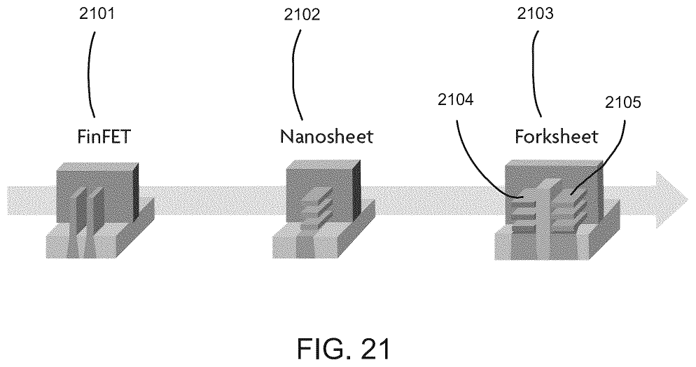

FIG. 21 illustrates three types of transistor structures used in ICs in accordance with one or more implementations as described herein.

Referring to FIG. 21, a FinFET transistor structure 2101, a nanosheet structure 2102, and a forksheet transistor structure 2103 are shown. This progression highlights the advancements in transistor design aimed at improving performance, efficiency, and scalability.

In the FinFET transistor structure 2101, a fin-like Si body protrudes vertically from a substrate, with a gate wrapped around three sides of the fin. This three-sided gate control improves the electrostatic characteristics of the transistor, allowing for better performance and lower leakage compared to traditional planar transistors.

In the nanosheet transistor structure 2102, also known as an MBCFET, unlike FETs, nanosheet transistors feature horizontal, stacked sheets of Si that are completely surrounded by the gate material, providing gate control on all four sides. This gate-all-around (GAA) configuration offers superior control over the channel, reducing leakage further and enabling lower power operation and higher performance.

In the forksheet transistor structure 2103, an additional insulating wall is inserted between NMOS transistors 2104 and PMOS transistors 2105. This wall allows the two types of transistors to be placed closer together, reducing the overall footprint of the transistor pair and improving the density of the circuit. The forksheet design structure 2103 aims to enhance the performance and scalability of ICs by providing better isolation and reducing parasitic capacitance between the transistors.

The progression from FinFET transistor structure 2101 to nanosheet transistor structure 2102 to forksheet transistor structure 2103 is a response to the industry's need for smaller, faster, and more efficient semiconductor devices. As devices scale down, maintaining and improving performance becomes increasingly challenging. The introduction of advanced stress engineering techniques, such as the ones described in this disclosure, are crucial for optimizing the performance of these next-generation transistor structures. By effectively transferring stress to the Si channel, the proposed system and methods ensure that advanced transistors can achieve the desired performance improvements.

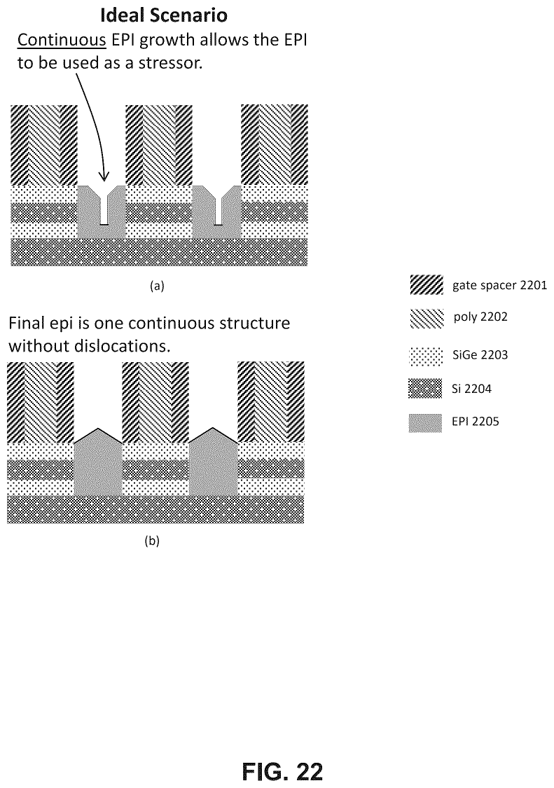

FIG. 22 illustrates an ideal scenario for EPI growth used to enhance transistor performance in accordance with one or more implementations as described herein.

Referring to FIG. 22, in the upper part of FIG. 22, labeled (a) of FIG. 22, the initial stages of EPI growth are shown. The regions labeled as gate spacer 2201 represent insulating materials that define the boundaries for the S/D regions of the transistor. In addition, the regions labeled as poly 2202 represent polysilicon, which is used as the gate material during the initial stages of the transistor fabrication process. Polysilicon gates control the flow of carriers in the channel region between the S/D. The polysilicon is later replaced with an HKMG stack to enhance the electrical properties and performance of the transistor.

Below the gate spacers, there are SiGe regions 2203, which may be used to introduce compressive stress in the Si channel, thereby enhancing hole mobility for PMOS transistors. The regions beneath the SiGe layers 2203 are the Si substrate regions 2204, forming the foundation of the transistor structure. The regions labeled as EPI 2205 indicate the EPI layer 2205 grown on top of the Si layer 2204 and SiGe layer 2203. In this ideal scenario, this layer grows continuously without interruptions, ensuring a smooth and defect-free crystalline structure.

The lower part of FIG. 22, labeled (b) of FIG. 22, depicts the final, ideal state of the EPI layer. In this stage, the EPI layer remains continuous and seamless, extending from the Si substrate through the S/D regions up to the gate spacers. The absence of defects such as dislocations or stacking faults is helpful for maintaining high stress transfer efficiency. A defect-free EPI layer ensures that the engineered stress is effectively transferred into the Si channel, thereby enhancing carrier mobility and improving the transistor's performance.

In this ideal scenario, the continuous EPI growth allows the EPI layer to function as an effective stressor. The uninterrupted growth ensures that the stress induced by the SiGe layer and other materials is efficiently transferred into the SI channel, which improves the performance of the transistor.

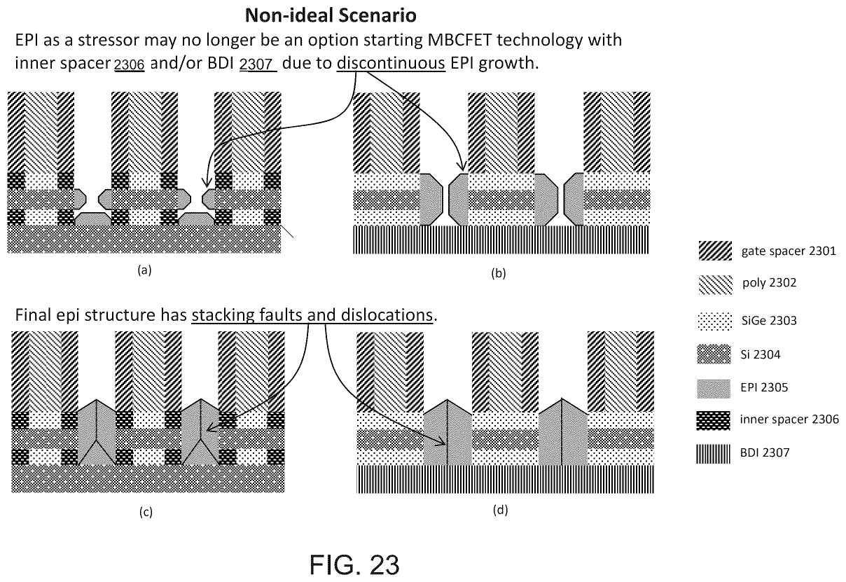

FIG. 23 illustrates a non-ideal scenario for EPI growth used to enhance transistor performance in accordance with one or more implementations as described herein. In FIG. 23, reference numerals 2301-2305 respectively correspond to similar components as reference numerals 2201-2205 in FIG. 22. Therefore, for convenience, the descriptions of reference numerals 2201-2205 may also apply to reference numerals 2301-2305, respectively.

Referring to FIG. 23, the non-ideal scenario of EPI growth used to enhance transistor performance is illustrated, highlighting the challenges encountered when using EPI as a stressor in advanced transistor structures. In the upper part of the figure, labeled (a) and (b) of FIG. 23, the initial stages of EPI growth are depicted, showing the complications introduced by additional components such as inner spacers 2306 and BDI 2307.

In the left portion of the upper section, labeled (a) of FIG. 23, the presence of inner spacers 2306 is illustrated. The inner spacers 2306, are insulating materials positioned between the gate spacers 2301 and the EPI regions 2305. These inner spacers 2306 create a discontinuous surface for the EPI region 2305, preventing it from growing seamlessly. The right portion of the upper section, labeled (b) of FIG. 23, depicts the effect of BDI 2307, shown as a layer beneath the Si 2304 layer and SiGe 2303 layer. The BDI 2307 further disrupts the continuity of the EPI growth, leading to dislocations and stacking faults.

The lower part of FIG. 23, labeled (c) and (d) of FIG. 23, shows the final state of the EPI layer 2305 in this non-ideal scenario. The EPI structure 2305 is marred by stacking faults and dislocations, indicated by dashed lines and irregularities in the crystalline structure in (c) and (d) of FIG. 23. These defects significantly reduce the stress transfer efficiency to the Si channel, hindering the performance improvements that the EPI layer is intended to provide.

In this non-ideal scenario of FIG. 23, the discontinuous EPI growth caused by the presence of inner spacers 2306 and BDI 2307 results in a defective EPI layer 2305. These defects prevent effective stress transfer, leading to lower carrier mobility and reduced transistor performance.

Accordingly, FIG. 23 illustrates the challenges of using EPI as a stressor in advanced transistor structures with discontinuous surfaces and underscores the necessity of alternative methods, such as the proposed use of a dummy stressor material before depositing an EPI material, to enhance stress transfer efficiency and improve device performance.

In many semiconductor fabrication processes, a “gate last” process flow is predominantly used due to several considerations related to the thermal budget and the integrity of the HKMG stack. The “gate last” approach involves completing high-temperature processing steps before the final gate formation. This sequence is performed for several reasons.

Firstly, an S/D EPI growth stage, which is responsible for creating the highly doped regions necessary for the transistor's operation, may require high-temperature steps that can exceed 1000° C. These high temperatures may be helpful for achieving the desired material properties and doping concentrations. However, if the gate were to be formed before these high-temperature steps, the extreme heat would damage the delicate materials used in the gate stack, including the HKMG stack and other dielectric layers.

The HKMG stack may be composed of materials with various metal layers sensitive to high temperatures. Exposure to such high temperatures can lead to diffusion of the gate materials, degradation of the dielectric properties, and overall instability of the gate structure. This sensitivity necessitates the completion of all high-temperature processing steps before the gate formation, ensuring that the gate materials remain intact and functional.

The introduction of low-temperature EPI growth techniques opens the possibility of revisiting the gate last process flow. These new techniques enable the growth of S/D regions at significantly lower temperatures, which could mitigate the risk of damaging the HKMG stack. By leveraging these low-temperature processes, it becomes feasible to consider a “gate first” process flow, where the gate is formed before the final S/D EPI deposition stage. This approach can maintain the structural integrity of the gate while enhancing the stress transfer efficiency to the channel.

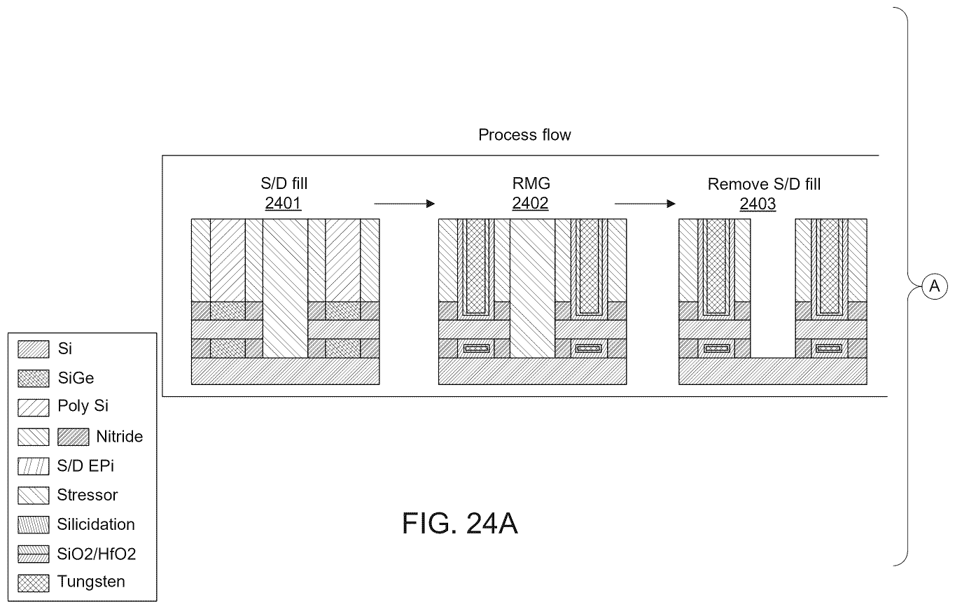

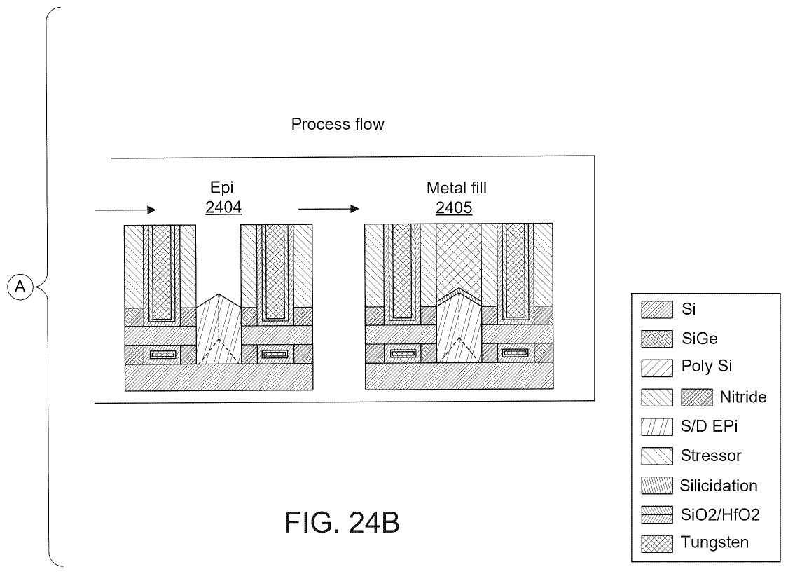

FIGS. 24A-24B illustrate a process flow for fabricating a transistor using a gate first process in accordance with one or more implementations as described herein. The gate first process includes five stages, 2401-2405, to fabricate a semiconductor device. A low-temperature (e.g., less than a predetermined temperature, such as 400 Celsius) EPI solution may be used to enable an EPI stage 2404 to occur after an RMG stage 2402. By filling the stressor material in stages 2401 before the EPI stage 2404, the stressor material (e.g., an S/D dielectric material) is deposited closer to the Si channel, having a larger impact on stress and thereby improving the stress transfer efficiency.

Other transistor fabricating processes may typically deposit a stressor material after an EPI growth stage. This may be called a “gate last” process. The techniques shown in FIGS. 24A-24B illustrate depositing a stressor material before an EPI growth stage. This may be called a “gate first” process.

Referring to FIGS. 24A-24B, the process begins with stage 2401, in which a stressor material (e.g., an S/D dielectric material) fills a region between channels. Since the EPI growth stage has not yet occurred, the stressor material (also referred to as a dummy stressor) may entirely fill the region up to the Si layer, and be directly in-line with the channel (e.g., dielectric and Si).

In stage 2402, the RMG is then deposited, encapsulating the channel with a gate. The gate may act like a cage, freezing the stress in the channel. Therefore, the RMG stage 2402 may enable channel stress retention even after the stressor material is removed.

Thus, in the stage 2403, when the stressor material is removed from the region between channels, channel stress is preserved. Subsequently, in stage 2404, the EPI material may be grown. This may be a low-temperature S/D EPI material to prevent damage to the HKMG stack. For example, the temperature of the EPI material may be less than a predetermined temperature (e.g., less than 400 Celsius, less than 550 Celsius, etc.).

Thus, even if the EPI material grown in the region between channels includes imperfections, such as stacking faults or dislocations, since the RMG gate stage has already been performed to preserve the channel stress around the gates.

Finally, in stage 2405, metal is filled into the region above the EPI material, grown in the region between the channels.

Thus, the gate first approach deposits any stressor material with high intrinsic stress to transfer the stress into the Si channel region instead of using the EPI itself as the stressor. The closer the stressor material is to the channel, the higher the stress transfer efficiency, which can be done by depositing the stressor material in the S/D region in stage 2401 before growing the low-temperature EPI material in stage 2405.

The semiconductor fabrication process shown in FIG. 24 may be applied to any transistor structure with discontinuous EPI growth in the S/D regions. The MBCFET may be one such transistor in which the fabrication process may be used to improve stress. The MBCFET, also known as a nanosheet transistor, may include an inner spacer, bottom dielectric isolation (BDI), or both inner spacer and BDI. Further, the transistor fabricated by the process in FIG. 24 can be any structure, including FinFETs, Forksheet FETs, or 3D stacked FETs, with discontinuous EPI growth in the S/D regions.

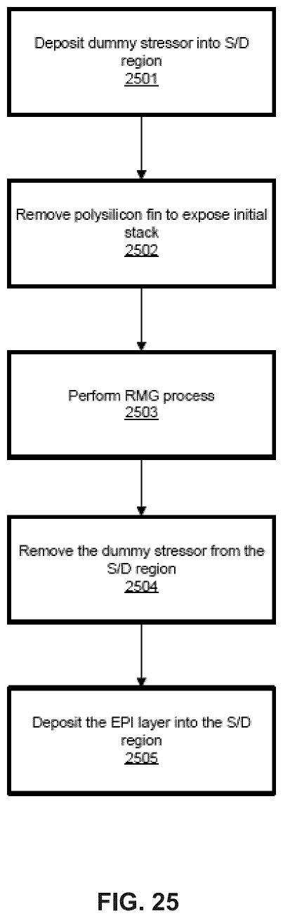

FIG. 25 is a flowchart illustrating a method of fabricating a transistor in accordance with one or more implementations as described herein. In alternative embodiments, some or all of the steps provided in FIG. 25 may be performed in a different order or simultaneously, however the step of depositing the EPI in 2505 should occur after the dummy stressor is deposited to the S/D region in step 2501. In addition, additional steps may be added or some of the steps may be omitted in accordance with various aspects of the present disclosure.

Referring to FIG. 25, in step 2501, a dummy stressor is deposited into the S/D region of the transistor. This region is located between a first sidewall and a second sidewall. The dummy stressor is intended to temporarily introduce stress into the Si channel, thereby enhancing the transistor's performance by improving carrier mobility. This deposition occurs before any EPI layer is added to the S/D region, ensuring effective stress transfer to the channel. The material used for the dummy stressor is typically one that can be easily removed later in the process, such as a high-stress dielectric or a temporary metal.

In step 2502, the polysilicon fin, which is located between the second sidewall and a third sidewall, is removed. This step exposes the initial stack of layers that form the transistor structure. The polysilicon fin serves as a placeholder in earlier fabrication steps, and its removal is necessary for the subsequent processing stages. This removal must be carefully controlled to avoid damaging the underlying layers and to ensure the initial stack is adequately exposed for further processing.

Following the removal of the polysilicon fin, an RMG process is performed in step 2503 to form the final gate structure. The RMG process is capable of locking in the stress within the channel, as it replaces the temporary dummy gate material with a final metal gate while preserving the stress characteristics induced by prior processing steps. The gate formation at this stage ensures that the stress remains in the Si channel.

After the RMG process, in step 2504, the dummy stressor is removed from the S/D region. This step clears the way for the deposition of the EPI layer. Although the dummy stressor is removed, the stress it induced in the Si channel remains, ensuring the channel retains the beneficial stress characteristics.

In step 2505, the EPI layer (also referred to as material, or film) is deposited into the S/D region. This layer may be a crystalline structure that matches a lattice of the underlying Si substrate. Materials such as SiGe may be used to introduce additional stress into the channel or to form the highly doped regions necessary for the source and drain of the transistor. After deposition of the EPI layer, then a metal may be deposited into the region between the first and second sidewalls, and on top of the EPI layer.

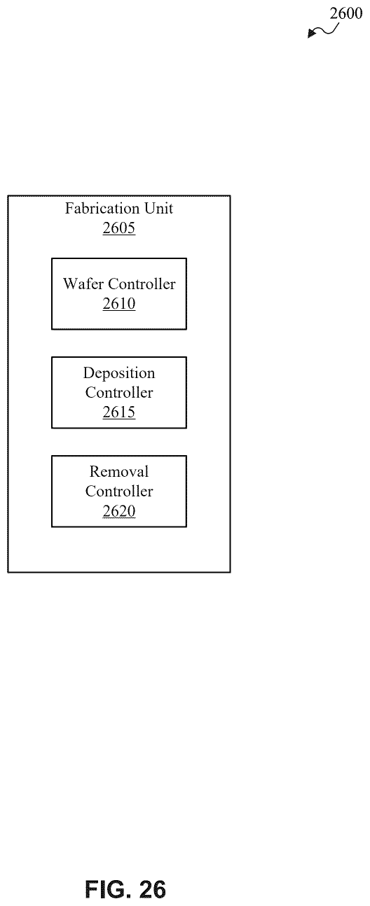

FIG. 26 illustrates an example system in accordance with one or more implementations as described herein. In the illustrated example, system 2600 may include fabrication unit 2605. As shown, fabrication unit 2605 may include wafer controller 2610, deposition controller 2615, and removal controller 2620.

Fabrication unit 2605 may be configured to perform semiconductor fabrication. Fabrication unit 2605 may be configured to fabricate Si wafers into ICs. System 2600, fabrication unit 2605, and/or at least one component of fabrication unit 2605 may perform one or more steps (e.g., deposition, removal, etching, doping, oxidation, lithography, metallization, etc.) to fabricate electronic circuits such as computer processors, microcontrollers, memory chips, and transistors, etc. In some cases, fabrication unit 2605 may perform photolithography and/or physio-chemical processes such as thermal oxidation, thin-film deposition, ion-implantation, etching, etc. Processes of fabrication unit 2605 may implement a variety of materials, including Si, germanium, compound semiconductors, nitrides, dielectrics, etc.

In some cases, wafer controller 2610 may perform wafer preparation, including transforming a semiconductor crystal into a thin, flat wafer with a smooth surface. Wafer controller 2610 may perform crystal growth, wafer slicing, polishing, and cleaning to generate the wafers.

Deposition controller 2615 may perform deposition on semiconductor fabrication. Deposition controller 2615 may perform one or more processes that grow, coat, and/or transfer one or more materials onto the wafer. Deposition controller 2615 may deposit semiconductors, semiconductor compounds (e.g., SiGe), metals (e.g., conductive material, tungsten, etc.), dielectrics, and/or other materials. Deposition controller 2615 may perform chemical vapor deposition (CVD), atomic layer deposition (ALD), magnetron sputtering, physical vapor deposition (PVD), and/or other deposition processes to deposit materials onto a wafer, semiconductor devices, etc.

Removal controller 2620 may remove materials from wafer, semiconductor devices, etc. Removal controller 2620 may perform any process that removes material from the wafer, such as wet etch processes, dry etch processes, chemical-mechanical planarization (CMP), and/or other removal processes.

In some examples, fabrication unit 2605 may include less or more components than those depicted in system 2600. System 2600 may include one or more devices (e.g., including fabrication unit) to fabricate semiconductor devices such as those described herein.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple compact disks (CDs), disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method of fabricating a transistor, the method comprising:
depositing a dummy stressor into a source and drain (S/D) region between a first sidewall and a second sidewall of the transistor before an epitaxial (EPI) layer is deposited into the S/D region;
removing a polysilicon fin between the second sidewall and a third sidewall of the transistor to expose an initial stack;
removing the dummy stressor from the S/D region; and
depositing the EPI layer into the S/D region.

2. The method of claim 1, further comprising:
depositing a metal between the first sidewall and the second sidewall after the EPI layer is deposited into the S/D region.

3. The method of claim 1, wherein depositing the dummy stressor into the S/D region further comprises depositing the dummy stressor into the S/D region to directly contact a Silicon (Si) substrate layer.

4. The method of claim 1, wherein depositing the dummy stressor into the S/D region further comprises transferring at least 50% of stress into a channel between the first sidewall and the second sidewall.

5. The method of claim 1, wherein a channel between the first sidewall and the second sidewall has a higher stress than the EPI layer.

6. The method of claim 1, wherein the EPI layer is deposited at a temperature that is less than 550 Celsius.

7. The method of claim 6, further comprising forming the first sidewall, the second sidewall, and the third sidewall over the channel structure,
wherein the channel structure is transverse to the first sidewall, the second sidewall, and the third sidewall.

8. A transistor comprising:
a dummy stressor deposited into a source and drain (S/D) region between a first sidewall and a second sidewall of the transistor;
an initial stack exposed by removing a polysilicon fin between the second sidewall and a third sidewall of the transistor; and
an epitaxial (EPI) layer deposited into the S/D region,
wherein the dummy stressor is removed from the S/D region before the EPI layer is deposited into the S/D region.

9. The transistor of claim 8, further comprising:
a metal deposited between the first sidewall and the second sidewall after the EPI layer is deposited into the S/D region.

10. The transistor of claim 8, wherein the dummy stressor directly contacts a Silicon (Si) substrate layer in the S/D region.

11. The transistor of claim 8, wherein at least 50% of the stress from the dummy stressor is transferred into a channel between the first sidewall and the second sidewall.

12. The transistor of claim 8, wherein a channel between the first sidewall and the second sidewall has a higher stress than the EPI layer.

13. The transistor of claim 8, further comprising:
a surface of the S/D region between the first sidewall and the second sidewall formed by etching a portion of a channel structure between the first sidewall and the second sidewall.

14. The transistor of claim 8, wherein the EPI layer is deposited at a temperature that is less than 550 Celsius.

15. A fabrication system comprising:
a deposition controller configured to:
deposit a dummy stressor into a source and drain (S/D) region between a first sidewall and a second sidewall of a transistor before an epitaxial (EPI) layer is deposited into the S/D region, and
deposit the EPI layer into the S/D region; and
a removal controller configured to:
remove a polysilicon fin between the second sidewall and a third sidewall of the transistor to expose an initial stack, and
remove the dummy stressor from the S/D region.

16. The fabrication system of claim 15, wherein the deposition controller is further configured to deposit a metal between the first sidewall and the second sidewall after the EPI layer is deposited into the S/D region.

17. The fabrication system of claim 15, wherein the deposition controller is further configured to deposit the dummy stressor into the S/D region to directly contact a Silicon (Si) substrate layer.

18. The fabrication system of claim 15, wherein depositing the dummy stressor into the S/D region further comprises transferring at least 50% of stress into a channel between the first sidewall and the second sidewall.

15. e fabrication system of claim 15, wherein a channel between the first sidewall and the second sidewall has a higher stress than the EPI layer.

20. The fabrication system of claim 15, further comprising:
an etching controller configured to etch a portion of a channel structure between the first sidewall and the second sidewall to form a surface of the S/D region between the first sidewall and the second sidewall.
